(19) United States
(12) Patent Application Publication
(10) Pub. No.: US 2026/0239598 A1
(43) Pub. Date: Aug. 13, 2026

(54) SEMICONDUCTOR DEVICE

(71) Applicant: SEMICONDUCTOR ENERGY LABORATORY CO., LTD., Atsugi-shi, Kanagawa-ken (JP)

(72) Inventors: Takanori MATSUZAKI, Atsugi, Kanagawa (JP); Hiroki INOUE, Atsugi, Kanagawa (JP); Yuki OKAMOTO, Ebina, Kanagawa (JP)

(21) Appl. No.: 19/471,484

(22) PCT Filed: Apr. 8, 2024
(86) PCT No.: PCT/IB2024/053402

§ 371 Date: Oct. 1, 2025

(30) Foreign Application Priority Data
Apr. 14, 2023 (JP) 2023-066030

(51) Int. Cl. H10B 12/00

(52) U.S. Cl. CPC H10B 12/00

(57) ABSTRACT

A semiconductor device with a novel structure is provided. The semiconductor device includes a first element layer and a second element layer including n (n is an integer greater than or equal to 2) element layers. The memory circuit includes n memory cells each having a function of retaining n-bit data. The n memory cells each include a first transistor and a second transistor and has a function of retaining a potential corresponding to the data by turning off the first transistor and a function of allowing a current with an amount corresponding to the data to flow by applying the potential to a gate of the second transistor. Any one of the n memory cells is provided in any one of the n element layers. A parallel number of the second transistors electrically connected to the second wiring is different between the n memory cells, and the parallel number corresponds to a power of two.

### TECHNICAL FIELD

One embodiment of the present invention relates to a semiconductor device and the like.

Note that one embodiment of the present invention is not limited to the above technical field. The technical field of the invention disclosed in this specification and the like relates to an object, a method, or a manufacturing method. Alternatively, one embodiment of the present invention relates to a process, a machine, manufacture, or a composition of matter. Thus, more specifically, examples of the technical field of one embodiment of the present invention disclosed in this specification include a semiconductor device, a display device, a light-emitting device, a power storage device, a storage device, a driving method thereof, and a manufacturing method thereof.

### BACKGROUND ART

A transistor including a metal oxide semiconductor (preferably an oxide semiconductor containing In, Ga, and Zn) in its semiconductor layer is known as a kind of transistor. It is known that a transistor including a metal oxide in its semiconductor layer has an extremely low off-state current. Note that in this specification, a transistor including a metal oxide in its semiconductor layer is referred to as an oxide semiconductor transistor, a metal oxide transistor, an OS transistor, or the like in some cases.

The use of an OS transistor enables a semiconductor device having excellent data retention characteristics to be formed. For example, Patent Document 1 describes that a semiconductor device can be downsized by stacking a peripheral circuit and a cell array.

### REFERENCE

### Patent Document

[Patent Document 1] Japanese Published Patent Application No. 2012-256821

### SUMMARY OF THE INVENTION

### Problems to be Solved by the Invention

To achieve higher performance and lower power consumption of a computing system, a further reduction in power consumption, an increase in operating speed, downsizing, an increase in storage capacity, and the like, in a semiconductor device such as a DRAM are required.

An object of one embodiment of the present invention is to provide a semiconductor device with a novel structure. Another object of one embodiment of the present invention is to provide a semiconductor device that is excellent in reducing power consumption, increasing operation speed, downsizing, or increasing storage capacity.

Note that the objects of one embodiment of the present invention are not limited to the objects listed above. The objects listed above do not preclude the presence of other objects. Note that the other objects are objects that are not described in this section and will be described below. The objects that are not described in this section can be derived from the description of the specification, the drawings, and the like and can be extracted as appropriate from the description by those skilled in the art. Note that one embodiment of the present invention is to achieve at least one of the objects listed above and/or the other objects.

### Means for Solving the Problems

One embodiment of the present invention is a semiconductor device including a first element layer and a second element layer including n (n is an integer greater than or equal to 2) element layers; the second element layer is provided over the first element layer; a bit line driver circuit is provided in the first element layer; a memory circuit is provided in the second element layer; the memory circuit includes n memory cells each having a function of retaining n-bit data; the memory cell includes a first transistor and a second transistor and has a function of retaining a potential corresponding to the data by turning off the first transistor and a function of allowing a current with an amount corresponding to the data to flow by applying the potential to a gate of the second transistor; the bit line driver circuit has a function of writing, to the n memory cells, the potential corresponding to the data through a first wiring and a function of reading, from the n memory cells, the current with the amount corresponding to the data through a second wiring; and a parallel number of the second transistors electrically connected to the second wiring is different between the n memory cells, and the parallel number corresponds to a power of two.

In the semiconductor device of one embodiment of the present invention, it is preferable that the first element layer include the first transistor including a first semiconductor layer including silicon in a channel formation region, and the second element layer include the second transistor including a second semiconductor layer including an oxide semiconductor in a channel formation region.

In the semiconductor device of one embodiment of the present invention, the oxide semiconductor preferably includes at least In.

In the semiconductor device of one embodiment of the present invention, each of the first wiring and the second wiring preferably includes a portion provided in a direction perpendicular to a substrate provided with the first element layer.

Note that other embodiments of the present invention will be described in the following embodiments and the drawings.

### Effect of the Invention

One embodiment of the present invention can provide a novel semiconductor device or the like. Another embodiment of the present invention can provide a semiconductor device that is excellent in reducing power consumption, increasing operation speed, downsizing, or increasing storage capacity.

Note that the description of these effects does not preclude the presence of other effects. Note that one embodiment of the present invention does not need to have all these effects. Note that effects other than these will be apparent from the description of the specification, the drawings, the claims, and the like and effects other than these can be derived from the description of the specification, the drawings, the claims, and the like.

### BRIEF DESCRIPTION OF THE DRAWINGS

FIG. 1A and FIG. 1B are diagrams each illustrating a structure example of a semiconductor device.

FIG. 2A to FIG. 2D are diagrams each illustrating a structure example of a semiconductor device.

FIG. 3 is a diagram illustrating a structure example of a semiconductor device.

FIG. 4 is a diagram illustrating a structure example of a semiconductor device.

FIG. 5 is a diagram illustrating a structure example of a semiconductor device.

FIG. 6 is a diagram illustrating a structure example of a semiconductor device.

FIG. 7 is a diagram illustrating a structure example of a semiconductor device.

FIG. 8A to FIG. 8C are diagrams illustrating structure examples of a semiconductor device.

FIG. 9 is a diagram illustrating a structure example of a semiconductor device.

FIG. 10A to FIG. 10D are diagrams illustrating a structure example of a semiconductor device.

FIG. 11 is a diagram illustrating a structure example of a semiconductor device.

FIG. 12A is a diagram illustrating a structure example of a semiconductor device. FIG. 12B is a diagram illustrating an equivalent circuit of the semiconductor device.

FIG. 13 is a block diagram illustrating a structure example of a semiconductor device.

FIG. 14A to FIG. 14H are diagrams illustrating circuit structure examples of memory cells.

FIG. 15A and FIG. 15B are perspective views illustrating structure examples of a semiconductor device.

FIG. 16 is a block diagram illustrating a CPU.

FIG. 17A and FIG. 17B are perspective views of a semiconductor device.

FIG. 18A and FIG. 18B are perspective views of a semiconductor device.

FIG. 19A and FIG. 19B are diagrams each illustrating a hierarchy of a variety of storage devices. FIG. 20A and FIG. 20B are diagrams each illustrating an example of an electronic component.

FIG. 21A and FIG. 21B are diagrams each illustrating an example of an electronic device, and FIG. 21C to FIG. 21E are diagrams illustrating an example of a large computer.

FIG. 22 is a diagram illustrating an example of a device for space.

FIG. 23 is a diagram illustrating an example of a storage system that can be used in a data center.

### MODE FOR CARRYING OUT THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Therefore, the present invention should not be construed as being limited to the description of embodiments below.

In addition, in the drawings, the size, the layer thickness, or the region is exaggerated for clarity in some cases. Therefore, the size, the layer thickness, or the region is not limited to the illustrated scale. Note that the drawings schematically illustrate ideal examples, and embodiments of the present invention are not limited to shapes, values, and the like illustrated in the drawings.

Furthermore, unless otherwise specified, off-state current in this specification and the like refers to drain current of a transistor in an OFF state (also referred to as a non-conduction state or a cutoff state). Unless otherwise specified, an OFF state in an n-channel transistor refers to a state where voltage V_{gs} between its gate and source is lower than threshold voltage Vₜₕ (in a p-channel transistor, higher than Vₜₕ).

In this specification and the like, a metal oxide is an oxide of metal in a broad sense. Metal oxides are classified into an oxide insulator, an oxide conductor (including a transparent oxide conductor), an oxide semiconductor (also simply referred to as an OS), and the like. For example, in the case where a metal oxide is used for an active layer of a transistor, the metal oxide is referred to as an oxide semiconductor in some cases. That is, in the case where an OS transistor is stated, the OS transistor can also be referred to as a transistor including a metal oxide or an oxide semiconductor.

### Embodiment 1

In this embodiment, a structure example of a semiconductor device will be described. The semiconductor device described in one embodiment of the present invention has a function of a storage device (memory device) having a function of storing data. Particularly in this embodiment, the structure example of the semiconductor device including memory circuits that retain digital data of two or more bits and include a plurality of memory cells which can convert the digital data into a current amount corresponding to an analog value of the digital data and from which the current amount can be read will be described.

### Structure Example of Semiconductor Device

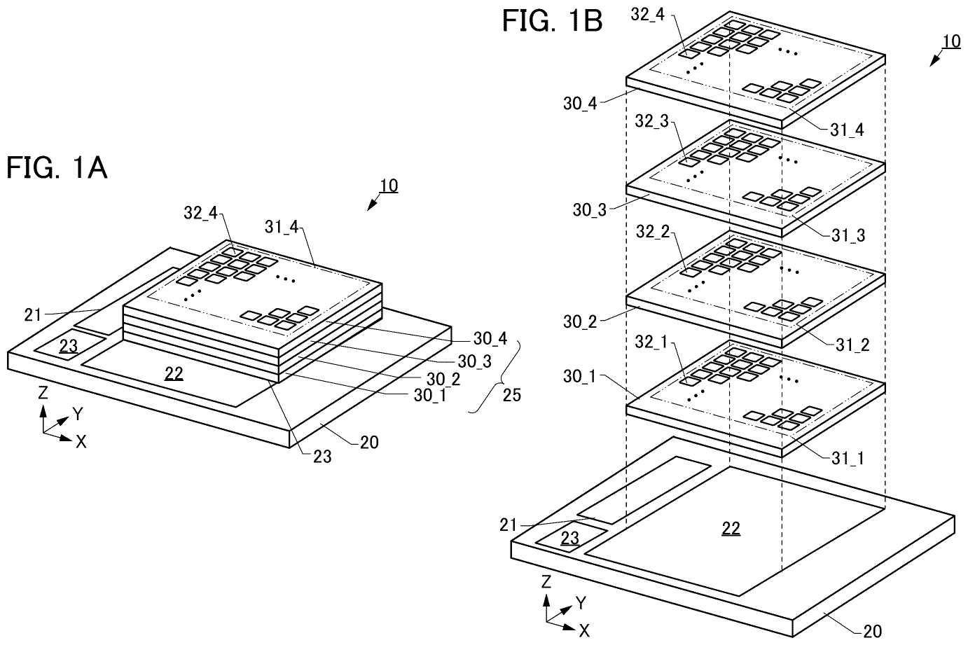

FIG. 1A is a schematic perspective view of the semiconductor device of one embodiment of the present invention. A semiconductor device 10 illustrated in FIG. 1A includes an element layer 20 and an element layer 25. In some cases, the element layer 20 is referred to as a first element layer and the element layer 25 is referred to as a second element layer. The element layer 25 includes element layers 30_1 to 30_n (n is an integer greater than or equal to 2. FIG. 1A illustrates the element layers 30_1 to 30_4 as an example.). FIG. 1B is a perspective view illustrating the element layer 20 and the element layers 30_1 to 30_4 separately in the structure of FIG. 1A. Note that the element layer refers to a layer where a semiconductor element such as a transistor or a capacitor is provided.

FIG. 1A and FIG. 1B illustrate the case where n in the n element layers 30_1 to 30_n is 4. In the element layers 30_1 to 30_4 illustrated in FIG. 1A and FIG. 1B, the first layer is illustrated as the element layer 30_1, the second layer is illustrated as the element layer 30_2, the third layer is illustrated as the element layer 30_3, and the fourth layer is illustrated as the element layer 30_4. Note that in this embodiment and the like, a simple term “element layer 30” is sometimes used to describe matters related to all the element layers 30_1 to 30_n or matters common to the element layers 30_1 to 30_n. Similar descriptions will be given for reference numerals of other components provided in the element layers 30_1 to 30_4.

The element layer 20 includes a word line driver circuit 21, a bit line driver circuit 22, and a memory controller portion 23. The element layer 20 includes a transistor in which a semiconductor layer including a channel formation region includes silicon (a Si transistor). The channel formation region of the Si transistor can be provided in the semiconductor layer provided in a silicon substrate or on the silicon substrate, for example.

In particular, silicon with high crystallinity, such as single crystal silicon or polycrystalline silicon, is used for the Si transistor included in the element layer 20. When the element layer 20 includes silicon with high crystallinity, high field-effect mobility can be achieved and operation at higher speed is possible. Thus, the element layer 20 can be provided with circuits that are preferably operated at high speed, such as the word line driver circuit 21, the bit line driver circuit 22, and the memory controller portion 23.

The element layers 30_1 to 30_4 illustrated in FIG. 1A and FIG. 1B include memory circuits 31_1 to 31_4, respectively. The memory circuits 31_1 to 31_4 include memory cells 32_1 to 32_4, respectively. The element layers 30_1 to 30_4 including the memory circuits 31_1 to 31 4 can be stacked over a region where the bit line driver circuit 22 provided in the element layer 20 is provided. With this structure, a signal transmission distance between the bit line driver circuit 22 and the memory cells 32_1 to 32_4 can be shortened.

A transistor included in the element layer 30 is a transistor in which a semiconductor layer including a channel formation region includes an oxide semiconductor (an OS transistor). The element layer 30 including the OS transistor can be stacked over the element layer 20. In the semiconductor device 10 illustrated in FIG. 1A and FIG. 1B, a state where the element layers 30_1 to 30_4 are stacked over the element layer 20 is illustrated. When the element layers 30_1 to 30_4 are provided over the element layer 20, the transistor density per unit area can be increased.

Examples of a metal oxide used in an OS transistor include indium oxide, gallium oxide, and zinc oxide. The metal oxide preferably contains two or three kinds selected from indium, an element M, and zinc. Note that the element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium. In particular, the element M is preferably one or more kinds selected from aluminum, gallium, yttrium, and tin.

It is particularly preferable to use an oxide containing indium (In), gallium (Ga), and zinc (Zn) (also referred to as IGZO) for the metal oxide. Alternatively, it is preferable to use an oxide containing indium, tin, and zinc (also referred to as ITZO). Alternatively, it is preferable to use an oxide containing indium, gallium, tin, and zinc. Alternatively, it is preferable to use an oxide containing indium (In), aluminum (Al), and zinc (Zn) (also referred to as IAZO). Alternatively, it is preferable to use an oxide containing indium (In), aluminum (Al), gallium (Ga), and zinc (Zn) (also referred to as IAGZO). Alternatively, it is preferable to use an oxide containing indium (In), gallium (Ga), zinc (Zn), and tin (Sn) (also referred to as IGZTO).

The OS transistors included in the element layers 30_1 to 30_4 can be used in the plurality of memory cells 32_1 to 32_4 included in the memory circuits 31_1 to 31_4. The off-state current of the OS transistor is extremely low. Accordingly, charge corresponding to data written to the memory cells 32 can be retained in the capacitors for a long time. That is, data once written can be retained for a long time in the memory cells 32. Thus, the frequency of data refresh can be reduced, and power consumption of the semiconductor device 10 of one embodiment of the present invention can be reduced. Note that a memory circuit including a memory cell that includes an OS transistor is referred to as an “OS memory” in some cases.

The element layers 30_1 to 30_4 are provided to be stacked in a direction perpendicular or substantially perpendicular to a surface of the element layer 20. In other words, the element layers 30_1 to 30_4 are provided to be stacked in the direction perpendicular or substantially perpendicular to a surface of a substrate provided with the element layer 20. With this structure, the density of transistors per unit area to be increased.

In each of the schematic cross-sectional views illustrated in FIG. 1A and FIG. 1B, the direction perpendicular or substantially perpendicular to the surface of the element layer 20 is defined as a Z direction in order to explain the position of components. Note that for easy understanding, the Z direction is sometimes referred to as a direction perpendicular to the surface of the element layer 20 in this specification. Note that “substantially perpendicular” refers to a state where an arrangement angle is greater than or equal to 85 degrees and less than or equal to 95 degrees.

Note that in this specification, the drawings, and the like, an X direction, a Y direction, and a Z direction are sometimes defined to describe arrangement of components. For example, in the schematic view illustrated in FIG. 1B, the X direction, the Y direction, and the Z direction are defined to describe the arrangement of components included in the semiconductor device 10. The X direction, the Y direction, and the Z direction are perpendicular or substantially perpendicular to each other.

The word line driver circuit 21 has a function of outputting a write word signal that controls an on state or an off state of transistors for writing data (write transistors) at once or row by row. The word line driver circuit 21 has a function of outputting a read word signal that controls an on state or an off state of transistors for selecting data (selection transistors) at once or row by row. The write transistor and the selection transistor function as switches. With the word line driver circuit 21, data can be written by selecting memory cells included in the memory circuit 31 row by row or data can be read by collectively selecting memory cells included in the memory circuit 31.

The bit line driver circuit 22 has a function of supplying, to a wiring functioning as a write bit line, data to be written to the memory cells 32. With the bit line driver circuit 22, data can be written and read in accordance with the selection of the memory cells 32 by the word line driver circuit 21. Note that supplying, to a retention node (also referred to as a node FN) of the memory cell 32, the potential of the wiring functioning as the write bit line through a transistor for data writing included in the memory cell 32 is also referred to as writing data.

In addition, the bit line driver circuit 22 has a function of reading data retained in the memory circuits 31 on the basis of the potential of a wiring functioning as a read bit line, which changes in accordance with data read from the memory cells 32. Note that making current corresponding to a potential retained in the retention node of the memory cell 32 flow through the wiring functioning as the read bit line is also referred to as reading data. The bit line driver circuit 22 includes an analog-digital converter circuit for converting the potential having an analog value that changes with current flow into digital data. Since the bit line driver circuit 22 includes the analog-digital converter circuit, digital data corresponding to the potential having the analog value can be output.

As the analog-digital converter circuit that can be used for the bit line driver circuit 22, an A/D converter circuit of a flash type, a successive approximation type, a multi-slope type, or the like can be used. Note that the analog-digital converter circuit used for the bit line driver circuit 22 is preferably a flash-type analog-digital converter circuit. The flash-type analog-digital converter circuit excels in high-speed operation and can perform data reading at high speed.

The memory controller portion 23 has a function of outputting a signal for controlling the word line driver circuit 21 and the bit line driver circuit 22 in accordance with data written to the memory circuits 31 and a control signal such as an address signal, and controlling data writing to or data reading from the memory circuits 31.

In the case of the n element layers 30_1 to 30_n, the memory circuits 31 have a function of retaining n-bit digital data in the memory cells 32_1 to 32_n. In the structures illustrated in FIG. 1A and FIG. 1B, the memory circuits 31_1 to 31_4 retain 4-bit digital data.

For example, in the memory circuits 31_1 to 31_4, the memory circuit 31_1 retains data of the least significant bit (the first bit). Next, the memory circuit 31_2 retains the second bit data. Next, the memory circuit 31_3 retains the third bit data. Then, the memory circuit 31_4 retains data of the most significant bit (the fourth bit). Note that in the memory circuits 31_1 to 31_4, the memory circuit 31_1 may retain the data of the most significant bit (the fourth bit) and the memory circuit 31_4 may retain the data of the least significant bit (the first bit).

Note that in this specification and the like, the least significant bit is the first bit for easy understanding. The number of bits of digital data corresponds to the number of digits represented in binary numbers. For example, 4-bit digital data is represented by 4-digit digital data. The 4-digit digital data can be converted into an analog value by weighting the digital data to the magnitudes of 2⁰, 2¹, 2², and 2³ in decimal numbers. In the case where the magnitude represented by the least significant bit is 1 or 0, 4-bit digital data can be represented by an analog value with a magnitude of 0 to 15.

The memory cells 32_1 to 32_4 each include a transistor (a write transistor) that enables retention of charge corresponding to a potential written to the memory cells 32_1 to 32_4 when being turned off. The gate potential of a transistor (a read transistor) supplied with a potential corresponding to the retained charge in the memory cell 32 corresponds to the potential of the retention node FN of the memory cell 32. The write transistor is sometimes referred to as a first transistor. The read transistor is sometimes referred to as a second transistor.

In each of the memory cells 32_1 to 32_4, binary data (data d) is retained. The binary data is data for selecting whether or not current flows through the memory cells 32. Binary data writing is performed for each of the memory cells 32_1 to 32 4. When data to be written to the memory cell is binary data, the circuit structure of the bit line driver circuit 22 can be downsized as compared with the case where data having more than two levels is written.

The memory cells 32_1 to 32_4 each include the transistor (the read transistor) in which a potential corresponding to the charge retained in the memory cells 32_1 to 32_4 is applied to a gate. The memory cell 32_1 has a function of allowing current I to flow in accordance with a potential corresponding to retained data d₁.

The memory cell 32_2 has a function of allowing current 2I, that is, current with an amount twice the amount of the current I, to flow in accordance with a potential corresponding to retained data d₂. The current 2I can be obtained by setting the parallel number of the read transistors through which the current I flows to two. That is, the memory cell 32_2 has a structure including two transistors in each of which a gate is connected to the retention node FN and the current I can flow between a source and a drain.

The memory cell 32_3 has a function of allowing current 4I, that is, current with an amount four times the amount of the current I, to flow in accordance with a potential corresponding to retained data d₃. The current 4I can be obtained by setting the parallel number of the read transistors through which the current I flows to four. That is, the memory cell 32_3 has a structure including four transistors in each of which a gate is connected to the retention node FN and the current I can flow between a source and a drain.

The memory cell 32_4 has a function of allowing current 8I, that is, current with an amount eight times the amount of the current I, to flow in accordance with a potential corresponding to retained data d₄. The current 8I can be obtained by setting the parallel number of the read transistors through which the current I flows to eight. That is, the memory cell 32_4 has a structure including eight transistors in each of which a gate is connected to the retention node FN and the current I can flow between a source and a drain.

As described above, in the memory cells 32 provided in the memory circuit 31 in the n-th element layer 30, the parallel number of the read transistors is different between the plurality of memory cells 32 and the parallel number of the read transistors corresponds to a power of two. With this structure, a current amount corresponding to the number of bits can be supplied in accordance with the binary data retained in the memory cells 32 and the parallel number (the number of transistors connected in parallel) of the read transistors that is different between the memory cells 32. Thus, data with a large number of bits can be written by writing the binary data, and reading of the analog value can be performed by adding the current amounts flowing through the memory cells 32. Thus, in the case where data with a large number of bits is retained, the number of memory cells 32 can be reduced, whereby the size or power consumption of the semiconductor device can be reduced.

Note that when the transistors are connected in parallel, gates are connected to the same node, and sources and drains are connected to a common wiring through a switch or the like. That is, when the transistors are connected in parallel, current with an amount corresponding to the parallel number can be made to flow in accordance with a potential applied to each gate in the case where the transistors have the same size.

In the case where current flows through all of the memory cells 32_1 to 32_4, current I_{ALL} is d×I+d₂×2I+d₃×4I+d₄×8I, that is, the current I_{ALL} is 16-level analog value. Data can be read at once from the memory cells 32_1 to 32_4 included in the element layers 30_1 to 30_4. The 16-level analog value corresponds to 4-bit digital data. In the memory cells 32_1 to 32_4, depending on the combination of the retained data d₁ to d₄, conversion into a current amount corresponding to the analog value can be performed in accordance with the 4-bit digital data, and the current amount can be read.

In the structure of one embodiment of the present invention, when binary data is written, data corresponding to the bit number including and after the second bit can be retained. Thus, data written from the bit line driver circuit 22 to the memory cells 32 can be binary. In addition, charging and discharging of a wiring functioning as the read bit line in data reading need to be performed only once; thus, reduction in power consumption and high-speed operation can be achieved. When the number of stacked element layers included in the element layer 30 is increased, the number of bits of digital data that can be retained can be increased.

Each of the memory cells 32 that have the above-described function is preferably an OS memory, and it is particularly preferable to use a NOSRAM (Nonvolatile Oxide Semiconductor Random Access Memory). A memory cell in a NOSRAM is a two-transistor (2T) or three-transistor (3T) gain cell. In the NOSRAM, data is rewritten by charging and discharging of the capacitor; therefore, there is theoretically no limit on rewrite cycles, and low energy control is possible.

Furthermore, the NOSRAM can nondestructively read the written data and thus is suitable for long-time data retention.

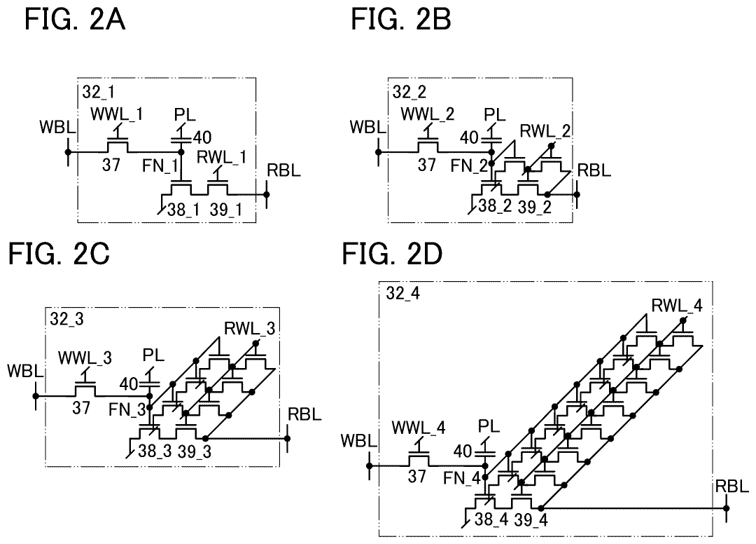

FIG. 2A to FIG. 2D are diagrams illustrating circuit structures of the memory cells 32_1 to 32_4 each including a NOSRAM that is a three-transistor (3T) gain cell.

FIG. 2A illustrates an example of a circuit structure of the memory cell 32_1 for making the current I flow in accordance with a potential corresponding to the retained data d₁. The memory cell 32_1 includes transistors 37, 38_1, and 39_1 and a capacitor 40. The transistors 37, 38_1, and 39_1 are a write transistor, a read transistor, and a selection transistor, respectively. The read transistor is a transistor to which a potential corresponding to charge retained in the memory cell 32_1 is supplied. The transistors 37, 38_1, and 39_1 can each include a back gate. The transistors 38 1 and 39_1 each include one transistor, and the parallel number of each of the transistors 38_1 and 39_1 is 1 (=2⁰). The memory cell 32_1 is connected to a wiring RWL_1, a wiring WWL_1, a wiring RBL, a wiring WBL, and a wiring PL. For example, a constant potential such as a ground potential is supplied to the wiring PL. Gates of the transistors 38_1 and 39_1 are connected to a retention node FN_1 and the wiring RWL_1, respectively.

FIG. 2B illustrates an example of a circuit structure of the memory cell 32_2 for making the current 2I flow in accordance with a potential corresponding to the retained data d₂. The memory cell 32_2 includes the transistor 37, transistors 38_2 and 39_2, and the capacitor 40. The transistors 37, 38_2, and 39_2 are the write transistor, a read transistor, and a selection transistor, respectively. The transistors 37, 38_2, and 39_2 can each include a back gate. The transistors 38_2 and 39_2 include a plurality of transistors connected in parallel, and the parallel number of each of the transistors 38_2 and 39_2 is 2 (=2¹). The memory cell 32_2 is connected to a wiring RWL_2, a wiring WWL_2, the wiring RBL, the wiring WBL, and the wiring PL. Gates of the transistors 38_2 and 39_2 are connected to a retention node FN_2 and the wiring RWL_2, respectively.

FIG. 2C illustrates an example of a circuit structure of the memory cell 32_3 for making the current 4I flow in accordance with a potential corresponding to the retained data d₃. The memory cell 32_3 includes the transistor 37, transistors 38_3 and 39_3, and the capacitor 40. The transistors 37, 38_3, and 39_3 are the write transistor, a read transistor, and a selection transistor, respectively. The transistors 37, 38_3, and 39_3 can each include a back gate. The transistors 38 3 and 39_3 include a plurality of transistors connected in parallel, and the parallel number of each of the transistors 38_3 and 39_3 is 4 (=2²). The memory cell 32_3 is connected to a wiring RWL_3, a wiring WWL_3, the wiring RBL, the wiring WBL, and the wiring PL. Gates of the transistors 38_3 and 39_3 are connected to a retention node FN_3 and the wiring RWL_3, respectively.

FIG. 2D illustrates an example of a circuit structure of the memory cell 32_4 for making the current 8I flow in accordance with a potential corresponding to the retained data d₄. The memory cell 32_4 includes the transistor 37, transistors 38_4 and 39_4, and the capacitor 40. The transistors 37, 38_4, and 39_4 are the write transistor, a read transistor, and a selection transistor, respectively. The transistors 37, 38_4, and 39_4 can each include a back gate. The transistors 38_4 and 39_4 include a plurality of transistors connected in parallel, and the parallel number of each of the transistors 38_4 and 39_4 is 8 (=2³). The memory cell 32_4 is connected to a wiring RWL_4, a wiring WWL_4, the wiring RBL, the wiring WBL, and the wiring PL. Gates of the transistors 38_4 and 39_4 are connected to a retention node FN_4 and the wiring RWL_4, respectively.

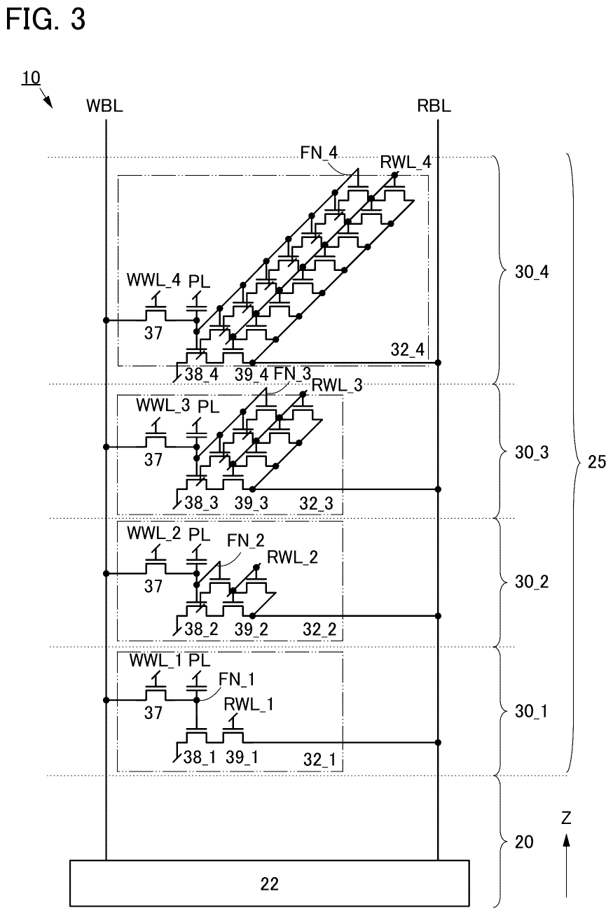

FIG. 3 is a diagram schematically illustrating a state where the structures of the memory cells 32_1 to 32_4 described above with reference to FIG. 2A to FIG. 2D are applied to the semiconductor device 10 including the element layer 25 (the element layers 30_1 to 30_4) stacked in the Z direction of the bit line driver circuit 22 in the element layer 20. The wiring WBL and the wiring RBL extend in the Z direction from the bit line driver circuit 22.

As illustrated in FIG. 3, the wiring WBL is connected to one of a source and a drain of the transistor 37 included in each of the memory cells 32_1 to 32_4. As illustrated in FIG. 3, the wiring RBL is connected to one of a source and a drain of each of the transistors 39_1 to 39_4 included in the memory cells 32_1 to 32_4. As each of the wirings WBL and RBL, a conductor provided to penetrate the element layer 30 such as a through-hole via provided in the Z direction perpendicular to the substrate can be used. With this structure, a signal transmission distance between the bit line driver circuit 22 and the memory cells 32_1 to 32_4 can be shortened.

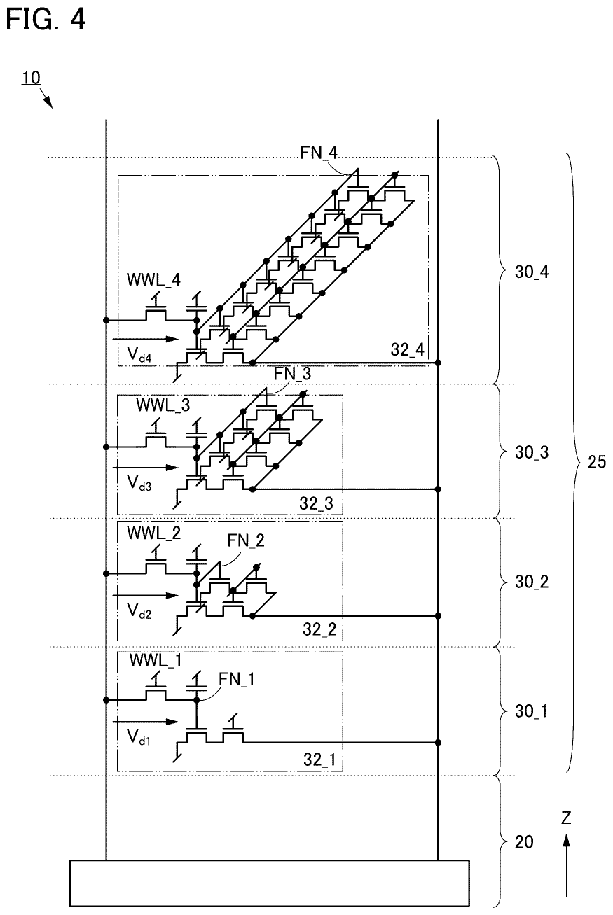

FIG. 4 is a diagram schematically illustrating a state where potentials V_{d1} to V_{d4} based on the binary data d₁ to d₄ are written in the structure of the semiconductor device 10 illustrated in FIG. 3.

Writing of the potentials V_{d1} to V_{d4} to the memory cells 32_1 to 32_4 is performed by supplying the potentials V_{d1} to V_{d4} to the wiring WBL. The potentials V_{d1} to V_{d4} are supplied to the wiring WBL, and the wirings WWL_1 to WWL_4 are sequentially set to H levels to turn on the transistors 37 included in the memory cells 32_1 to 32_4. Through the operation, the potentials V_{d1} to V_{d4} are written to the retention nodes FN_1 to FN_4, respectively, in the memory cells 32_1 to 32_4.

The potentials V_{d1} to V_{d4} written to the retention nodes FN_1 to FN_4 can be retained by turning off the transistors 37. In the memory cells 32_1 to 32_4, the frequency of updating the potentials V_{d1} to V_{d4} once written to the retention nodes FN_1 to FN_4 can be reduced, so that power consumption can be reduced.

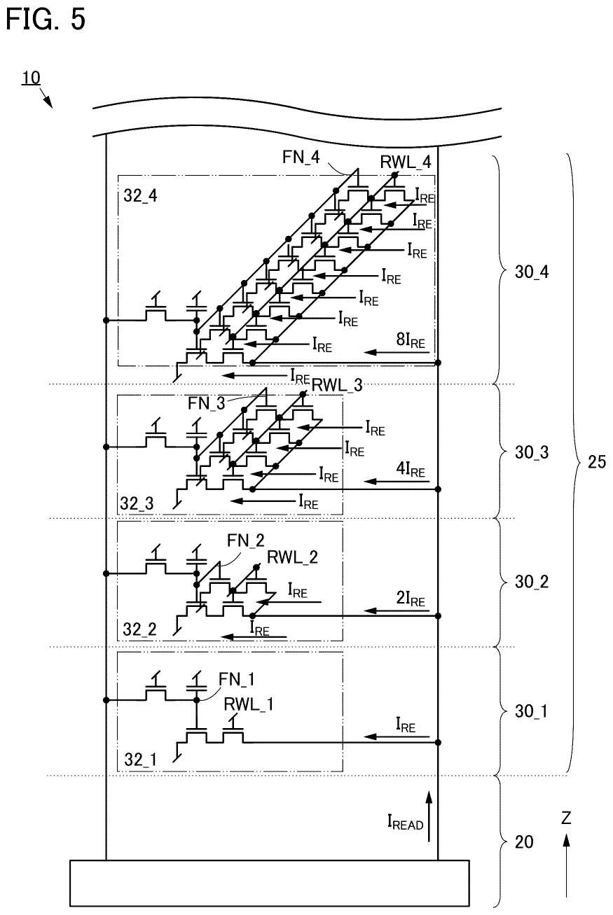

FIG. 5 is a diagram schematically illustrating a state where current IRE based on the potentials V_{d1} to V_{d4} written in FIG. 4 flows in the structure of the semiconductor device 10 illustrated in FIG. 3. The wirings RWL_1 to RWL_4 are brought into an on state at the same time, the potentials V_{d1} to V_{d4} are sequentially supplied, and the wirings WWL_1 to WWL_4 are sequentially set to H levels to turn on the transistors 37. Through the operation, current flows from the wiring RBL to the memory cells 32_1 to 32_4 in accordance with the potentials of the retention nodes FN_1 to FN_4. Specifically, the current IRE flows when the potentials of the retention nodes FN are at H levels, and the current does not flow when the potentials are at L levels. The amount of current differs between the memory cells 32_1 to 32_4 in accordance with the parallel numbers of the transistors 38_1 to 38_4 and 39_1 to 39_4.

For example, in the memory cell 32_1, the parallel number of each of the transistors 38_1 and 39_1 is 1 (=2⁰), so that the current I_{RE} flows. In the memory cell 32_2, the parallel number of each of the transistors 38_1 and 39_1 is 2 (=2¹), so that current 2I_{RE} flows. In the memory cell 32_3, the parallel number of each of the transistors 38_1 and 39_1 is 4 (=2²), so that current 4I_{RE} flows. In the memory cell 32_1, the parallel number of each of the transistors 38_1 and 39_1 is 8 (=2³), so that current 8I_{RE} flows. The amount of the current I_{ALL} flowing through the wiring RBL is d₁×I_{RE}+d₂×2I_{RE}+d₃×4I_{RE}+d₄×8I_{RE}, that is, the amount of a 16-level analog value. The amount of current represented by the analog value can be converted into digital data and output as appropriate in the bit line driver circuit 22.

In the operation of reading data in the semiconductor device 10, the wirings RWL_1 to RWL_4 are brought into an on state at the same time and data is read. Charging and discharging operation by current flowing through the wiring RBL is performed once. On the other hand, in the case of a structure in which data is sequentially read from the memory cells 32_1 to 32_4, charging and discharging operation by current flowing through the wiring RBL is performed four times. Thus, in the structure of the semiconductor device 10, power for charging and discharging of the wiring RBL can be reduced to ¼. Furthermore, the read operation can be performed at high speed.

Note that in the structure of the semiconductor device 10, the data of the memory cells 32_1 to 32_4 can be read separately by sequentially bringing the wirings RWL_1 to RWL_4 into an on state. The structure is not limited to making current flow to the memory cells 32 of the element layers 30 at the same time to read data; for example, a structure in which current flows to the memory cells 32 of the six element layers 30 among the eight element layers 30 at the same time to read data can also be employed. When eight of the element layers 30 are stacked, 8-bit digital data can be retained in the memory cells 32, in which case data corresponding to 1 Byte can be read.

### Structure Example of Integrated Circuit Including Semiconductor Device

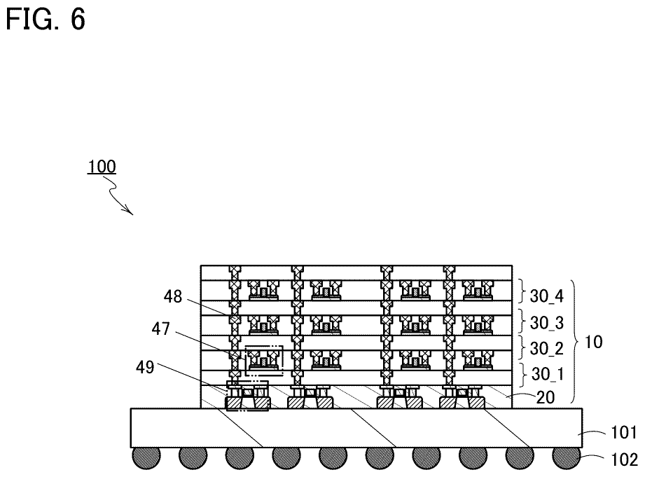

FIG. 6 illustrates an example of an integrated circuit (referred to as an IC chip) including the semiconductor device 10. The semiconductor device 10 can be one IC chip by mounting a plurality of element layers on a packaging substrate. FIG. 6 illustrates one example of the structure.

A schematic cross-sectional view of an IC chip 100 in FIG. 6 illustrates the semiconductor device 10 in which the element layer 20 serving as a base die is provided over a package substrate 101 and the four element layers 30_1 to 30_4, as an example, are stacked over the element layer 20. The package substrate 101 is provided with solder balls 102 for connecting the IC chip 100 to a printed circuit board or the like; electrodes 48 for connecting the element layer 20 and the element layers 30_1 to 30_4 can be provided in a process of manufacturing a transistor 49 that is a Si transistor or a transistor 47 that is an OS transistor.

The structure in FIG. 6 can be a monolithic structure where a technique using through electrodes such as a TSV (Through Silicon Via) or a Cu—Cu direct bonding technique is not used for connection between the element layer 20 including the transistors 49 and the element layers 30_1 to 30_4 including the transistors 47. The element layers 30_1 to 30_4 over the element layer 20 can have a structure where wirings provided together with the transistors 47 included in the element layers 30_1 to 30_4 are used as the electrodes 48 for being connected to the element layers in the upper layers or the lower layers.

The intervals between the wirings provided together with the transistors 47 can be more miniaturized than those between through electrodes used for a TSV or a Cu—Cu direct bonding technique. Thus, in the structure of the semiconductor device 10 illustrated in FIG. 6, the number of electrodes for being connected to the upper or lower element layers can be increased. Accordingly, the number of wirings (the number of signal lines) between storage circuits including the memory cells provided in the element layers 30_1 to 30_4 and the bit line driver circuit 22 provided in the element layer 20 can be increased. In other words, the number of channels between the arithmetic circuit and the storage circuits can be increased. Therefore, the transfer amount (bandwidth) of signals transmitted and received between the element layer 20 and the element layer 30 can be increased. The increase in the bandwidth can increase the data transfer amount per unit time.

This embodiment can be implemented in combination with the other embodiments described in this specification as appropriate.

### Embodiment 2

In this embodiment, structures of transistors that can be used in the semiconductor device described in the above embodiment will be described. For example, a structure where transistors having different electrical characteristics are stacked and provided will be described. With this structure, the degree of freedom in design of a semiconductor device can be increased. In addition, providing transistors having different electrical characteristics to be stacked can increase the integration degree of the semiconductor device.

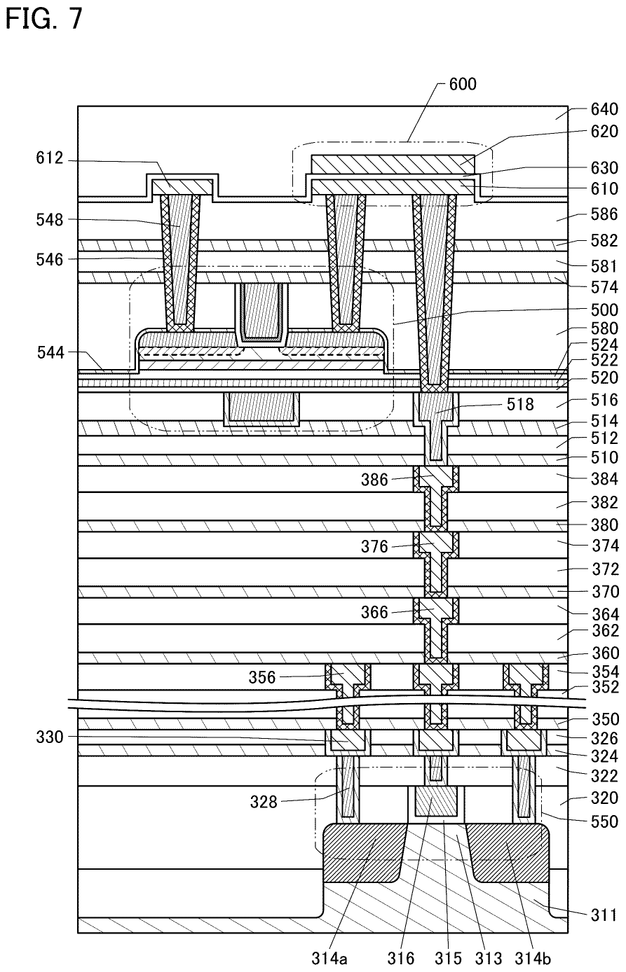

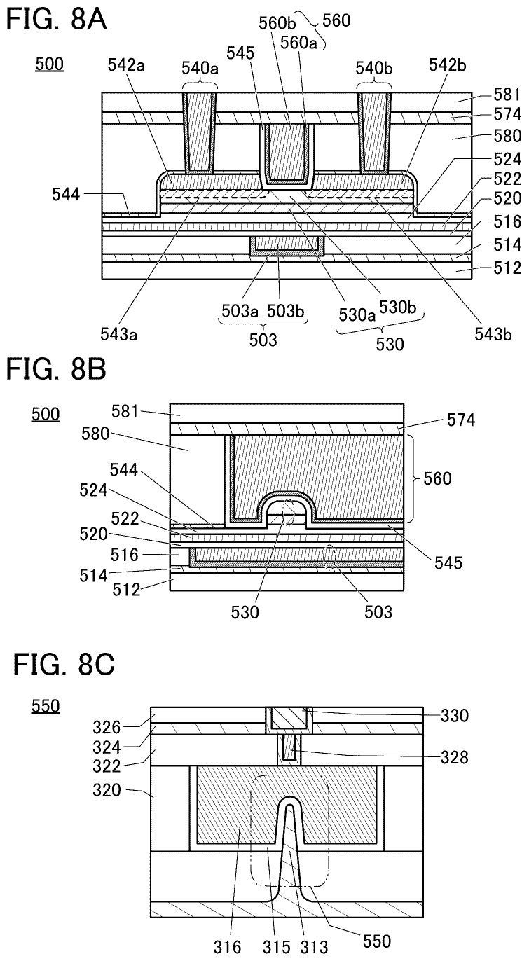

FIG. 7 illustrates part of a cross-sectional structure of a semiconductor device. The semiconductor device illustrated in FIG. 7 includes a transistor 550, a transistor 500, and a capacitor 600. FIG. 8A is a cross-sectional view of the transistor 500 in a channel length direction, FIG. 8B is a cross-sectional view of the transistor 500 in a channel width direction, and FIG. 8C is a cross-sectional view of the transistor 550 in a channel width direction. For example, the transistor 550 corresponds to the Si transistor described in the above embodiment, and the transistor 500 corresponds to an OS transistor.

In FIG. 7, the transistor 500 is provided above the transistor 550, and the capacitor 600 is provided above the transistor 550 and the transistor 500.

The transistor 550 is provided on a substrate 311 and includes a conductor 316, an insulator 315, a semiconductor region 313 that is part of the substrate 311, and a low-resistance region 314a and a low-resistance region 314b each functioning as a source region or a drain region.

As illustrated in FIG. 8C, in the transistor 550, the top surface and the side surface in the channel width direction of the semiconductor region 313 are covered with the conductor 316 with the insulator 315 therebetween. The use of such a Fin-type transistor as the transistor 550 can increase the effective channel width and thus improve on-state characteristics of the transistor 550. In addition, contribution of the electric field of a gate electrode can be increased, so that the off-state characteristics of the transistor 550 can be improved.

Note that the transistor 550 may be either a p-channel transistor or an n-channel transistor.

A region of the semiconductor region 313 where a channel is formed, a region in the vicinity thereof, the low-resistance region 314a and the low-resistance region 314b each functioning as a source region or a drain region, and the like preferably include a semiconductor such as a silicon-based semiconductor, and preferably include single crystal silicon. Alternatively, the regions may be formed using a material including Ge (germanium), SiGe (silicon germanium), GaAs (gallium arsenide), GaAlAs (gallium aluminum arsenide), or the like. A structure using silicon whose effective mass is controlled by applying stress to a crystal lattice and changing lattice spacing may be employed. Alternatively, the transistor 550 may be a HEMT (High Electron Mobility Transistor) using GaAs and GaAlAs, or the like.

The low-resistance region 314a and the low-resistance region 314b include an element that imparts n-type conductivity, such as arsenic or phosphorus, or an element that imparts p-type conductivity, such as boron, in addition to the semiconductor material used for the semiconductor region 313.

For the conductor 316 functioning as a gate electrode, a semiconductor material such as silicon including the element that imparts n-type conductivity, such as arsenic or phosphorus, or the element that imparts p-type conductivity, such as boron, or a conductive material such as a metal material, an alloy material, or a metal oxide material can be used.

Note that since a work function depends on the material of the conductor, the threshold voltage of the transistor can be adjusted by selecting the material of the conductor. Specifically, it is preferable to use a material such as titanium nitride or tantalum nitride for the conductor. Moreover, in order to ensure both conductivity and embeddability, it is preferable to use stacked layers of metal materials such as tungsten and aluminum for the conductor, and it is particularly preferable to use tungsten in terms of heat resistance.

The transistor 550 may be formed using an SOI (silicon on Insulator) substrate or the like.

In addition, as the SOI substrate, the following substrate may be used: a SIMOX (Separation by Implanted Oxygen) substrate that is formed in such a manner that after an oxygen ion is implanted into a mirror-polished wafer, an oxide layer is formed at a certain depth from a surface and defects generated in a surface layer are eliminated by high-temperature annealing, or an SOI substrate formed by using a Smart-Cut method in which a semiconductor substrate is cleaved by utilizing growth of a minute void, which is formed by implantation of a hydrogen ion, by heat treatment; an ELTRAN method (a registered trademark: Epitaxial Layer Transfer); or the like. A transistor formed using a single crystal substrate includes a single crystal semiconductor in a channel formation region.

An insulator 320, an insulator 322, an insulator 324, and an insulator 326 are sequentially stacked and provided to cover the transistor 550.

For the insulator 320, the insulator 322, the insulator 324, and the insulator 326, silicon oxide, silicon oxynitride, silicon nitride oxide, silicon nitride, aluminum oxide, aluminum oxynitride, aluminum nitride oxide, aluminum nitride, or the like is used, for example.

Note that in this specification, silicon oxynitride refers to a material that has a higher oxygen content than a nitrogen content, and silicon nitride oxide refers to a material that has a higher nitrogen content than an oxygen content. Moreover, in this specification, aluminum oxynitride refers to a material that has a higher oxygen content than a nitrogen content, and aluminum nitride oxide refers to a material that has a higher nitrogen content than an oxygen content.

The insulator 322 may have a function of a planarization film for eliminating a level difference caused by the transistor 550 or the like provided below the insulator 322. For example, the top surface of the insulator 322 may be planarized by planarization treatment using a chemical mechanical polishing (CMP) method or the like to increase planarity.

In addition, for the insulator 324, it is preferable to use a film having a barrier property that prevents diffusion of hydrogen, impurities, or the like from the substrate 311, the transistor 550, or the like into a region where the transistor 500 is provided.

For the film having a barrier property against hydrogen, for example, silicon nitride formed by a CVD method can be used. Here, diffusion of hydrogen into a semiconductor element including an oxide semiconductor, such as the transistor 500, degrades the characteristics of the semiconductor element in some cases. Therefore, a film that inhibits hydrogen diffusion is preferably used between the transistor 500 and the transistor 550. The film that inhibits hydrogen diffusion is specifically a film from which a small amount of hydrogen is released.

The amount of released hydrogen can be measured by thermal desorption spectroscopy (TDS) or the like, for example. The amount of hydrogen released from the insulator 324 that is converted into hydrogen atoms per area of the insulator 324 is less than or equal to 1×10¹⁶ atoms/cm², preferably less than or equal to 5×10¹⁵atoms/cm², in TDS analysis in a film-surface temperature range of 50° C. to 500° C., for example.

Note that the permittivity of the insulator 326 is preferably lower than that of the insulator 324. For example, the relative permittivity of the insulator 326 is preferably lower than 4, further preferably lower than 3. In addition, the relative permittivity of the insulator 326 is, for example, preferably 0.7 times or less, further preferably 0.6 times or less the relative permittivity of the insulator 324. When a material with low permittivity is used for the interlayer film, parasitic capacitance generated between wirings can be reduced.

In addition, a conductor 328, a conductor 330, and the like that are connected to the transistor 550 are embedded in the insulator 320, the insulator 322, the insulator 324, and the insulator 326. Note that the conductor 328 and the conductor 330 each have a function of a plug or a wiring. Furthermore, a plurality of conductors functioning as plugs or wirings are collectively denoted by the same reference numeral in some cases. Moreover, in this specification and the like, a wiring and a plug connected to the wiring may be a single component. That is, part of a conductor functions as a wiring in some cases and part of a conductor functions as a plug in other cases.

As a material for each of the plugs and wirings (the conductor 328, the conductor 330, and the like), a single layer or stacked layers of a conductive material such as a metal material, an alloy material, a metal nitride material, or a metal oxide material can be used. It is preferable to use a high-melting-point material that has both heat resistance and conductivity, such as tungsten or molybdenum, and it is preferable to use tungsten. Alternatively, it is preferable to form the plugs and wirings with a low-resistance conductive material such as aluminum or copper. The use of a low-resistance conductive material can reduce wiring resistance.

A wiring layer may be provided over the insulator 326 and the conductor 330. For example, in FIG. 7, an insulator 350, an insulator 352, and an insulator 354 are sequentially stacked and provided. Furthermore, a conductor 356 is formed in the insulator 350, the insulator 352, and the insulator 354. The conductor 356 has a function of a plug connected to the transistor 550 or a wiring. Note that the conductor 356 can be provided using a material similar to those for the conductor 328 and the conductor 330.

Note that for example, as the insulator 350, like the insulator 324, an insulator having a barrier property against hydrogen is preferably used. Furthermore, the conductor 356 preferably includes a conductor having a barrier property against hydrogen. In particular, the conductor having a barrier property against hydrogen is formed in an opening portion of the insulator 350 having a barrier property against hydrogen. With this structure, the transistor 550 and the transistor 500 can be separated with a barrier layer, so that hydrogen diffusion from the transistor 550 into the transistor 500 can be inhibited.

Note that for the conductor having a barrier property against hydrogen, tantalum nitride or the like is preferably used, for example. In addition, by stacking tantalum nitride and tungsten, which has high conductivity, diffusion of hydrogen from the transistor 550 can be inhibited while the conductivity as a wiring is kept. In that case, a structure where a tantalum nitride layer having a barrier property against hydrogen is in contact with the insulator 350 having a barrier property against hydrogen is preferable.

A wiring layer may be provided over the insulator 354 and the conductor 356. For example, in FIG. 7, an insulator 360, an insulator 362, and an insulator 364 are sequentially stacked and provided. Furthermore, a conductor 366 is formed in the insulator 360, the insulator 362, and the insulator 364. The conductor 366 has a function of a plug or a wiring. Note that the conductor 366 can be provided using a material similar to those for the conductor 328 and the conductor 330.

Note that for example, as the insulator 360, like the insulator 324, an insulator having a barrier property against hydrogen is preferably used. Furthermore, the conductor 366 preferably includes a conductor having a barrier property against hydrogen. In particular, the conductor having a barrier property against hydrogen is formed in an opening portion of the insulator 360 having a barrier property against hydrogen. With this structure, the transistor 550 and the transistor 500 can be separated with a barrier layer, so that hydrogen diffusion from the transistor 550 into the transistor 500 can be inhibited.

A wiring layer may be provided over the insulator 364 and the conductor 366. For example, in FIG. 7, an insulator 370, an insulator 372, and an insulator 374 are sequentially stacked and provided. Furthermore, a conductor 376 is formed in the insulator 370, the insulator 372, and the insulator 374. The conductor 376 has a function of a plug or a wiring. Note that the conductor 376 can be provided using a material similar to those for the conductor 328 and the conductor 330.

Note that for example, as the insulator 370, like the insulator 324, an insulator having a barrier property against hydrogen is preferably used. Furthermore, the conductor 376 preferably includes a conductor having a barrier property against hydrogen. In particular, the conductor having a barrier property against hydrogen is formed in an opening portion of the insulator 370 having a barrier property against hydrogen. With this structure, the transistor 550 and the transistor 500 can be separated with a barrier layer, so that hydrogen diffusion from the transistor 550 into the transistor 500 can be inhibited.

A wiring layer may be provided over the insulator 374 and the conductor 376. For example, in FIG. 7, an insulator 380, an insulator 382, and an insulator 384 are sequentially stacked and provided. Furthermore, a conductor 386 is formed in the insulator 380, the insulator 382, and the insulator 384. The conductor 386 has a function of a plug or a wiring. Note that the conductor 386 can be provided using a material similar to those for the conductor 328 and the conductor 330.

Note that for example, as the insulator 380, like the insulator 324, an insulator having a barrier property against hydrogen is preferably used. Furthermore, the conductor 386 preferably includes a conductor having a barrier property against hydrogen. In particular, the conductor having a barrier property against hydrogen is formed in an opening portion of the insulator 380 having a barrier property against hydrogen. With this structure, the transistor 550 and the transistor 500 can be separated with a barrier layer, so that hydrogen diffusion from the transistor 550 into the transistor 500 can be inhibited.

Although the wiring layer including the conductor 356, the wiring layer including the conductor 366, the wiring layer including the conductor 376, and the wiring layer including the conductor 386 are described above, the semiconductor device according to this embodiment is not limited thereto. Three or less wiring layers that are similar to the wiring layer including the conductor 356 may be provided, or five or more wiring layers that are similar to the wiring layer including the conductor 356 may be provided.

An insulator 510, an insulator 512, an insulator 514, and an insulator 516 are sequentially stacked and provided over the insulator 384. A substance having a barrier property against oxygen, hydrogen, or the like is preferably used for any of the insulator 510, the insulator 512, the insulator 514, and the insulator 516.

For example, for each of the insulator 510 and the insulator 514, it is preferable to use a film having a barrier property that prevents diffusion of hydrogen, impurities, or the like from the substrate 311, a region where the transistor 550 is provided, or the like into a region where the transistor 500 is provided. Therefore, a material similar to that for the insulator 324 can be used.

For the film having a barrier property against hydrogen, silicon nitride formed by a CVD method can be used, for example. Here, diffusion of hydrogen into a semiconductor element including an oxide semiconductor, such as the transistor 500, degrades the characteristics of the semiconductor element in some cases. Therefore, a film that inhibits hydrogen diffusion is preferably provided between the transistor 500 and the transistor 550. The film that inhibits hydrogen diffusion is specifically a film from which a small amount of hydrogen is released.

In addition, for the film having a barrier property against hydrogen, a metal oxide such as aluminum oxide, hafnium oxide, or tantalum oxide is preferably used for each of the insulator 510 and the insulator 514, for example.

In particular, aluminum oxide has an excellent blocking effect that prevents the passage of both oxygen and impurities such as hydrogen and moisture which are factors of fluctuation in electrical characteristics of the transistor. Accordingly, aluminum oxide can prevent mixing of impurities such as hydrogen and moisture into the transistor 500 during and after the manufacturing process of the transistor. In addition, release of oxygen from the oxide included in the transistor 500 can be inhibited. Therefore, aluminum oxide is suitably used for the protective film of the transistor 500.

In addition, for each of the insulator 512 and the insulator 516, a material similar to that for the insulator 320 can be used, for example. Furthermore, when a material with comparatively low permittivity is used for these insulators, parasitic capacitance generated between wirings can be reduced. A silicon oxide film, a silicon oxynitride film, or the like can be used for each of the insulator 512 and the insulator 516, for example.

Furthermore, a conductor 518, a conductor included in the transistor 500 (a conductor 503, for example), and the like are embedded in the insulator 510, the insulator 512, the insulator 514, and the insulator 516. Note that the conductor 518 has a function of a plug or a wiring that is connected to the capacitor 600 or the transistor 550. The conductor 518 can be provided using a material similar to those for the conductor 328 and the conductor 330.

In particular, the conductor 518 in a region in contact with the insulator 510 and the insulator 514 is preferably a conductor having a barrier property against oxygen, hydrogen, and water. With this structure, the transistor 550 and the transistor 500 can be separated with a layer having a barrier property against oxygen, hydrogen, and water, so that hydrogen diffusion from the transistor 550 into the transistor 500 can be inhibited.

The transistor 500 is provided above the insulator 516.

As illustrated in FIG. 8A and FIG. 8B, the transistor 500 includes the conductor 503 positioned to be embedded in the insulator 514 and the insulator 516; an insulator 520 positioned over the insulator 516 and the conductor 503; an insulator 522 positioned over the insulator 520; an insulator 524 positioned over the insulator 522; a metal oxide 530a positioned over the insulator 524; a metal oxide 530b positioned over the metal oxide 530a; a conductor 542a and a conductor 542b positioned apart from each other over the metal oxide 530b; an insulator 580 that is positioned over the conductor 542a and the conductor 542b and is provided with an opening portion formed to overlap with a region between the conductor 542a and the conductor 542b; an insulator 545 positioned on the bottom surface and the side surface of the opening portion; and a conductor 560 positioned on a formation surface of the insulator 545.

In addition, as illustrated in FIG. 8A and FIG. 8B, an insulator 544 is preferably positioned between the insulator 580 and the metal oxide 530a, the metal oxide 530b, the conductor 542a, and the conductor 542b. Furthermore, as illustrated in FIG. 8A and FIG. 8B, the conductor 560 preferably includes a conductor 560a provided inside the insulator 545 and a conductor 560b provided to be embedded inside the conductor 560a. Moreover, as illustrated in FIG. 8A and FIG. 8B, an insulator 574 is preferably positioned over the insulator 580, the conductor 560, and the insulator 545.

Note that in this specification and the like, the metal oxide 530a and the metal oxide 530b are sometimes collectively referred to as a metal oxide 530.

Note that the transistor 500 is illustrated to have a structure where two layers, the metal oxide 530a and the metal oxide 530b, are stacked in the region where the channel is formed and its vicinity; however, the present invention is not limited thereto. For example, a single layer of the metal oxide 530b or a stacked-layer structure of three or more layers may be provided.

In addition, although the conductor 560 has a stacked-layer structure of two layers in the transistor 500, the present invention is not limited thereto. For example, the conductor 560 may have a single-layer structure or a stacked-layer structure of three or more layers. Furthermore, the transistor 500 illustrated in FIG. 7 and FIG. 8A is an example and the structure is not limited thereto; an appropriate transistor is used in accordance with a circuit structure, a driving method, or the like.

Here, the conductor 560 functions as a gate electrode of the transistor, and the conductor 542a and the conductor 542b each function as a source electrode or a drain electrode. As described above, the conductor 560 is formed to be embedded in the opening portion of the insulator 580 and the region sandwiched between the conductor 542a and the conductor 542b. The positions of the conductor 560, the conductor 542a, and the conductor 542b with respect to the opening portion of the insulator 580 are selected in a self-aligned manner. That is, in the transistor 500, the gate electrode can be positioned between the source electrode and the drain electrode in a self-aligned manner. Thus, the conductor 560 can be formed without an alignment margin, which results in a reduction in the area occupied by the transistor 500. Accordingly, miniaturization and higher integration of the semiconductor device can be achieved.

In addition, since the conductor 560 is formed in the region between the conductor 542a and the conductor 542b in a self-aligned manner, the conductor 560 does not have a region overlapping with the conductor 542a or the conductor 542b. Thus, parasitic capacitance formed between the conductor 560 and each of the conductor 542a and the conductor 542b can be reduced. As a result, the switching speed of the transistor 500 can be increased, and the transistor 500 can have high frequency characteristics.

The conductor 560 sometimes functions as a first gate (also referred to as top gate) electrode. In addition, the conductor 503 sometimes functions as a second gate (also referred to as bottom gate) electrode. In that case, by changing a potential applied to the conductor 503 not in synchronization with but independently of a voltage applied to the conductor 560, the threshold voltage of the transistor 500 can be controlled. In particular, when a negative potential is applied to the conductor 503, the threshold voltage of the transistor 500 can be made higher than 0 V, and the off-state current can be reduced. Thus, drain current at the time when a potential applied to the conductor 560 is 0 V can be made lower in the case where a negative potential is applied to the conductor 503 than in the case where a negative potential is not applied to the conductor 503.

The conductor 503 is positioned to overlap with the metal oxide 530 and the conductor 560. Thus, when a potential is applied to the conductor 560 and the conductor 503, an electric field generated from the conductor 560 and an electric field generated from the conductor 503 are connected, so that the channel formation region formed in the metal oxide 530 can be covered.

In this specification and the like, a transistor structure where a channel formation region is electrically surrounded by an electric field of a first gate electrode is referred to as a surrounded channel (S-channel) structure. In addition, the S-channel structure disclosed in this specification and the like has a structure different from a Fin-type structure and a planar structure. Meanwhile, the S-channel structure disclosed in this specification and the like can also be regarded as a kind of Fin-type structure. Note that in this specification and the like, the Fin-type structure refers to a structure where at least two or more surfaces (specifically, two surfaces, three surfaces, four surfaces, or the like) of a channel are covered with a gate electrode. With the Fin-type structure and the S-channel structure, resistance to a short-channel effect can be increased, that is, a transistor in which a short-channel effect does not easily occur can be provided.

When the transistor has the S-channel structure, the channel formation region can be electrically surrounded. Note that since the S-channel structure is a structure where the channel formation region is electrically surrounded, it can also be said that the S-channel structure is a structure substantially equivalent to a GAA (Gate All Around) structure or an LGAA (Lateral Gate All Around) structure. When the transistor has the S-channel structure, the GAA structure, or the LGAA structure, a channel formation region that is formed at an interface between the metal oxide 530 and a gate insulator or in the vicinity of the interface can be the entire bulk of the metal oxide 530. Accordingly, the density of current flowing through the transistor can be improved, which can be expected to improve the on-state current of the transistor or increase the field-effect mobility of the transistor.

In addition, the conductor 503 has a structure similar to that of the conductor 518; a conductor 503a is formed in contact with an inner wall of an opening portion in the insulator 514 and the insulator 516, and a conductor 503b is formed on the inner side. Note that although the conductor 503a and the conductor 503b are stacked in the transistor 500, the present invention is not limited thereto. For example, the conductor 503 may be provided as a single layer or to have a stacked-layer structure of three or more layers.

Here, for the conductor 503a, a conductive material that has a function of inhibiting diffusion of impurities such as a hydrogen atom, a hydrogen molecule, a water molecule, and a copper atom (through which the impurities do not easily pass) is preferably used. Alternatively, it is preferable to use a conductive material that has a function of inhibiting diffusion of oxygen (e.g., at least one of an oxygen atom, an oxygen molecule, and the like) (through which oxygen does not easily pass). Note that in this specification, the function of inhibiting diffusion of impurities or oxygen means a function of inhibiting diffusion of any one or all of the impurities and oxygen.

For example, when the conductor 503a has a function of inhibiting diffusion of oxygen, a reduction in conductivity of the conductor 503b due to oxidation can be inhibited.

In addition, in the case where the conductor 503 also functions as a wiring, a conductive material with high conductivity that includes tungsten, copper, or aluminum as its main component is preferably used for the conductor 503b. Note that although the conductor 503 is illustrated to have a stacked layer of the conductor 503a and the conductor 503b in this embodiment, the conductor 503 may have a single-layer structure.

The insulator 520, the insulator 522, and the insulator 524 have a function of a second gate insulating film.

Here, an insulator including oxygen more than that in the stoichiometric composition is preferably used as the insulator 524 in contact with the metal oxide 530. Such oxygen is easily released from the insulator by heating. In this specification and the like, oxygen released by heating is sometimes referred to as “excess oxygen”. That is, a region including excess oxygen (also referred to as an “excess-oxygen region”) is preferably formed in the insulator 524. When such an insulator including excess oxygen is provided in contact with the metal oxide 530, oxygen vacancies (Vo) in the metal oxide 530 can be reduced and the reliability of the transistor 500 can be improved. Note that when hydrogen enters the oxygen vacancies in the metal oxide 530, such defects (hereinafter, referred to as VoH in some cases) serve as donors and generate electrons serving as carriers in some cases. In addition, in some cases, bonding of part of hydrogen to oxygen bonded to a metal atom generates electrons serving as carriers. Thus, a transistor using an oxide semiconductor that includes a large amount of hydrogen is likely to have normally-on characteristics. Moreover, hydrogen in an oxide semiconductor is easily transferred by stress such as heat or an electric field; thus, the reliability of the transistor might be reduced when the oxide semiconductor includes a large amount of hydrogen. In one embodiment of the present invention, VoH in the metal oxide 530 is preferably reduced as much as possible so that the metal oxide 530 becomes a highly purified intrinsic or substantially highly purified intrinsic oxide. It is important to remove impurities such as moisture and hydrogen in an oxide semiconductor (this treatment is also referred to as “dehydration” or “dehydrogenation treatment”) and to compensate for oxygen vacancies by supplying oxygen to the oxide semiconductor (this treatment is also referred to as “oxygen adding treatment”) in order to obtain an oxide semiconductor whose VoH is sufficiently reduced. When an oxide semiconductor with sufficiently reduced impurities such as VoH is used for a channel formation region of a transistor, stable electrical characteristics can be given.

As the insulator including the excess-oxygen region, specifically, an oxide material that releases part of oxygen by heating is preferably used. An oxide that releases oxygen by heating is an oxide film in which the amount of released oxygen converted into oxygen atoms is greater than or equal to 1.0×10¹⁸atoms/cm³, preferably greater than or equal to 1.0×10¹⁹atoms/cm³, further preferably greater than or equal to 2.0×10¹⁹ atoms/cm³ or greater than or equal to 3.0×10²⁰ atoms/cm³ in TDS (Thermal Desorption Spectroscopy) analysis. Note that the temperature of the film surface in the TDS analysis is preferably within the range of higher than or equal to 100° C. and lower than or equal to 700° C., or higher than or equal to 100° C. and lower than or equal to 400° C.

In addition, any one or more of heat treatment, microwave treatment, and RF treatment may be performed in a state in which the insulator including the excess-oxygen region and the metal oxide 530 are in contact with each other. By the treatment, water or hydrogen in the metal oxide 530 can be removed. For example, in the metal oxide 530, dehydrogenation can be performed when reaction in which a bond of VoH is cut occurs, i.e., reaction of “VoH→Vo+H” occurs. Part of hydrogen generated at this time is bonded to oxygen and is removed as H₂O from the metal oxide 530 or an insulator in the vicinity of the metal oxide 530 in some cases. In other cases, part of hydrogen is gettered by the conductors 542a and 542b.

In addition, for the microwave treatment, for example, it is suitable to use an apparatus including a power supply that generates high-density plasma or an apparatus including a power supply that applies RF to a substrate side. For example, high-density oxygen radicals can be generated with the use of an oxygen-containing gas and high-density plasma, and by applying RF to the substrate side, the oxygen radicals generated by the high-density plasma can be efficiently introduced into the metal oxide 530 or the insulator in the vicinity of the metal oxide 530. Furthermore, pressure in the microwave treatment is higher than or equal to 133 Pa, preferably higher than or equal to 200 Pa, further preferably higher than or equal to 400 Pa. Moreover, as a gas introduced into an apparatus for performing the microwave treatment, for example, oxygen and argon are used and the oxygen flow rate ratio (O₂/(O₂+Ar)) is lower than or equal to 50 %, preferably higher than or equal to 10 % and lower than or equal to 30 %.

In addition, in the manufacturing process of the transistor 500, it is suitable to perform the heat treatment with the surface of the metal oxide 530 exposed. The heat treatment is performed at higher than or equal to 100° C. and lower than or equal to 450° C., further preferably higher than or equal to 350° C. and lower than or equal to 400° C., for example. Note that the heat treatment is performed in a nitrogen gas or inert gas atmosphere, or an atmosphere including an oxidizing gas at higher than or equal to 10 ppm, higher than or equal to 1 %, or higher than or equal to 10 %. For example, the heat treatment is preferably performed in an oxygen atmosphere. Accordingly, oxygen can be supplied to the metal oxide 530 to reduce oxygen vacancies (Vo). Alternatively, the heat treatment may be performed under reduced pressure. Alternatively, the heat treatment may be performed in such a manner that heat treatment is performed in a nitrogen gas or inert gas atmosphere, and then heat treatment is performed in an atmosphere including an oxidizing gas at higher than or equal to 10 ppm, higher than or equal to 1 %, or higher than or equal to 10 % in order to compensate for released oxygen. Alternatively, the heat treatment may be performed in such a manner that heat treatment is performed in an atmosphere including an oxidizing gas at higher than or equal to 10 ppm, higher than or equal to 1 %, or higher than or equal to 10 %, and then heat treatment is successively performed in a nitrogen gas or inert gas atmosphere.

Note that oxygen adding treatment performed on the metal oxide 530 can promote reaction in which oxygen vacancies in the metal oxide 530 are filled with supplied oxygen, i.e., reaction of “Vo+O→null”. Furthermore, hydrogen remaining in the metal oxide 530 reacts with supplied oxygen, so that the hydrogen can be removed as H₂O (dehydration). This can inhibit recombination of hydrogen remaining in the metal oxide 530 with oxygen vacancies and formation of VoH.

In addition, in the case where the insulator 524 includes an excess-oxygen region, it is preferable that the insulator 522 have a function of inhibiting diffusion of oxygen (e.g., an oxygen atom, an oxygen molecule, or the like) (through which oxygen does not easily pass).

When the insulator 522 has a function of inhibiting diffusion of oxygen, impurities, or the like, oxygen included in the metal oxide 530 is not diffused into the insulator 520 side, which is preferable. Furthermore, the conductor 503 can be inhibited from reacting with oxygen included in the insulator 524, the metal oxide 530, or the like.

For the insulator 522, a single layer or stacked layers of an insulator including what is called a high-k material such as aluminum oxide, hafnium oxide, an oxide including aluminum and hafnium (hafnium aluminate), tantalum oxide, zirconium oxide, lead zirconate titanate (PZT), strontium titanate (SrTiO₃), or (Ba, Sr)TiO₃ (BST) are preferably used, for example. As miniaturization and higher integration of transistors progress, a problem such as off-state current might arise because of a thinner gate insulating film. When a high-k material is used for an insulator functioning as the gate insulating film, a gate potential during transistor operation can be reduced while the physical thickness is maintained.

It is particularly preferable to use an insulator including an oxide of one or both of aluminum and hafnium, which is an insulating material having a function of inhibiting diffusion of impurities, oxygen, and the like (through which oxygen does not easily pass). Aluminum oxide, hafnium oxide, an oxide including aluminum and hafnium (hafnium aluminate), or the like is preferably used for the insulator including an oxide of one or both of aluminum and hafnium. In the case where the insulator 522 is formed using such a material, the insulator 522 functions as a layer that inhibits release of oxygen from the metal oxide 530 or mixing of impurities such as hydrogen from the periphery of the transistor 500 into the metal oxide 530.

Alternatively, aluminum oxide, bismuth oxide, germanium oxide, niobium oxide, silicon oxide, titanium oxide, tungsten oxide, yttrium oxide, or zirconium oxide may be added to these insulators, for example. Alternatively, these insulators may be subjected to nitriding treatment. A stack of the insulator and silicon oxide, silicon oxynitride, or silicon nitride may be used.

In addition, it is preferable that the insulator 520 be thermally stable. For example, silicon oxide and silicon oxynitride are suitable because they are thermally stable. Furthermore, the combination of an insulator that is a high-k material and silicon oxide or silicon oxynitride enables the insulator 520 to have a stacked-layer structure that has thermal stability and high relative permittivity.

Note that in the transistor 500 in FIG. 8A and FIG. 8B, the insulator 520, the insulator 522, and the insulator 524 are illustrated as the second gate insulating film having a stacked-layer structure of three layers; however, the second gate insulating film may be a single layer or may have a stacked-layer structure of two layers or four or more layers. In that case, without limitation to a stacked-layer structure formed of the same material, a stacked-layer structure formed of different materials may be employed.

In the transistor 500, a metal oxide functioning as an oxide semiconductor is used as the metal oxide 530 including the channel formation region.

The metal oxide functioning as an oxide semiconductor may be formed by a sputtering method or an ALD (Atomic Layer Deposition) method. Note that the metal oxide functioning as an oxide semiconductor will be described in detail in another embodiment.

In addition, as the metal oxide functioning as the channel formation region in the metal oxide 530, a metal oxide whose bandgap is wider than or equal to 2 eV, preferably wider than or equal to 2.5 eV is preferably used. The use of a metal oxide having such a wide bandgap can reduce the off-state current of the transistor.

When the metal oxide 530 includes the metal oxide 530a under the metal oxide 530b, it is possible to inhibit diffusion of impurities into the metal oxide 530b from the components formed below the metal oxide 530a.

Note that the metal oxide 530 preferably has a plurality of oxide layers that differ in the atomic ratio of metal atoms. Specifically, the atomic ratio of the element M to the constituent elements in the metal oxide used as the metal oxide 530a is preferably higher than the atomic ratio of the element M to the constituent elements in the metal oxide used as the metal oxide 530b. In addition, the atomic ratio of the element M to In in the metal oxide used as the metal oxide 530a is preferably higher than the atomic ratio of the element M to In in the metal oxide used as the metal oxide 530b. Furthermore, the atomic ratio of In to the element M in the metal oxide used as the metal oxide 530b is preferably higher than the atomic ratio of In to the element M in the metal oxide used as the metal oxide 530a.

In addition, the energy of the conduction band minimum of the metal oxide 530a is preferably higher than the energy of the conduction band minimum of the metal oxide 530b. In other words, the electron affinity of the metal oxide 530a is preferably smaller than the electron affinity of the metal oxide 530b.

Here, the energy level of the conduction band minimum gradually changes at a junction portion of the metal oxide 530a and the metal oxide 530b. In other words, the energy level of the conduction band minimum at the junction portion of the metal oxide 530a and the metal oxide 530b continuously changes or is continuously connected. This can be achieved by decreasing the density of defect states in a mixed layer formed at the interface between the metal oxide 530a and the metal oxide 530b.

Specifically, when the metal oxide 530a and the metal oxide 530b include a common element (as a main component) in addition to oxygen, a mixed layer with a low density of defect states can be formed. For example, in the case where the metal oxide 530b is an In—Ga—Zn oxide, an In—Ga—Zn oxide, a Ga—Zn oxide, gallium oxide, or the like is preferably used for the metal oxide 530a.

At this time, the metal oxide 530b serves as a main carrier path. When the metal oxide 530a has the above structure, the density of defect states at the interface between the metal oxide 530a and the metal oxide 530b can be made low. Thus, the influence of interface scattering on carrier conduction is small, and the transistor 500 can have high on-state current.

Note that although this embodiment illustrates an example of the metal oxide 530 having a two-layer structure of the metal oxide 530a and the metal oxide 530b over the metal oxide 530a, the metal oxide 530 is not limited thereto. For example, the metal oxide 530 may have a three-layer structure of the metal oxide 530a, the metal oxide 530b, and a metal oxide 530c that are formed in this order. When the metal oxide 530c has a composition equivalent to that of the metal oxide 530a, it is possible to inhibit diffusion of impurities into the metal oxide 530b from the components formed above the metal oxide 530c. In addition, when a structure where the metal oxide 530b is sandwiched between the metal oxide 530a and the metal oxide 530c (what is called an embedded channel structure) is employed, the channel formation region can be kept away from an insulating film interface. Note that when the embedded channel structure is employed, carrier interface scattering can be reduced, and a transistor that has high field-effect mobility can be achieved.

The conductor 542a and the conductor 542b functioning as the source electrode and the drain electrode are provided over the metal oxide 530b. For the conductor 542a and conductor 542b, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy including the above metal element; an alloy including a combination of the above metal elements; or the like. For example, it is preferable to use tantalum nitride, titanium nitride, tungsten, a nitride including titanium and aluminum, a nitride including tantalum and aluminum, ruthenium oxide, ruthenium nitride, an oxide including strontium and ruthenium, an oxide including lanthanum and nickel, or the like. In addition, tantalum nitride, titanium nitride, a nitride including titanium and aluminum, a nitride including tantalum and aluminum, ruthenium oxide, ruthenium nitride, an oxide including strontium and ruthenium, and an oxide including lanthanum and nickel are preferable because they are oxidation-resistant conductive materials or materials that retain their conductivity even after absorbing oxygen. Furthermore, a metal nitride film of tantalum nitride or the like is preferable because it has a barrier property against hydrogen or oxygen.

In addition, although the conductor 542a and the conductor 542b each having a single-layer structure are illustrated in FIG. 8A, a stacked-layer structure of two or more layers may be employed. For example, it is preferable to stack a tantalum nitride film and a tungsten film. Alternatively, a titanium film and an aluminum film may be stacked. Alternatively, a two-layer structure where an aluminum film is stacked over a tungsten film, a two-layer structure where a copper film is stacked over a copper-magnesium-aluminum alloy film, a two-layer structure where a copper film is stacked over a titanium film, or a two-layer structure where a copper film is stacked over a tungsten film may be employed.

Other examples include a three-layer structure where a titanium film or a titanium nitride film is formed, an aluminum film or a copper film is stacked over the titanium film or the titanium nitride film, and a titanium film or a titanium nitride film is formed over the aluminum film or the copper film; and a three-layer structure where a molybdenum film or a molybdenum nitride film is formed, an aluminum film or a copper film is stacked over the molybdenum film or the molybdenum nitride film, and a molybdenum film or a molybdenum nitride film is formed over the aluminum film or the copper film. Note that a transparent conductive material including indium oxide, tin oxide, or zinc oxide may be used.

In addition, as illustrated in FIG. 8A, a region 543a and a region 543b are sometimes formed as low-resistance regions at an interface between the metal oxide 530 and the conductor 542a (the conductor 542b) and in the vicinity of the interface. In that case, the region 543a functions as one of a source region and a drain region, and the region 543b functions as the other of the source region and the drain region. Furthermore, the channel formation region is formed in a region between the region 543a and the region 543b.

When the conductor 542a (the conductor 542b) is provided to be in contact with the metal oxide 530, the oxygen concentration in the region 543a (the region 543b) sometimes decreases. In addition, a metal compound layer that includes the metal included in the conductor 542a (the conductor 542b) and the component of the metal oxide 530 is sometimes formed in the region 543a (the region 543b). In such a case, the carrier concentration of the region 543a (the region 543b) increases, and the region 543a (the region 543b) becomes a low-resistance region.

The insulator 544 is provided to cover the conductor 542a and the conductor 542b and inhibits oxidation of the conductor 542a and the conductor 542b. In that case, the insulator 544 may be provided to cover the side surface of the metal oxide 530 and to be in contact with the insulator 524.

A metal oxide including one kind or two or more kinds selected from hafnium, aluminum, gallium, yttrium, zirconium, tungsten, titanium, tantalum, nickel, germanium, neodymium, lanthanum, magnesium, and the like can be used for the insulator 544. Alternatively, silicon nitride oxide, silicon nitride, or the like can be used for the insulator 544.

It is particularly preferable to use an insulator including an oxide of one or both of aluminum and hafnium, such as aluminum oxide, hafnium oxide, or an oxide including aluminum and hafnium (hafnium aluminate), as the insulator 544. In particular, hafnium aluminate has higher heat resistance than a hafnium oxide film. Therefore, hafnium aluminate is preferable because it is not easily crystallized by heat treatment in a later step. Note that the insulator 544 is not an essential component when the conductor 542a and the conductor 542b are oxidation-resistant materials or materials that do not significantly lose their conductivity even after absorbing oxygen. Design is appropriately set in consideration of required transistor characteristics.

When the insulator 544 is included, diffusion of impurities such as water and hydrogen included in the insulator 580 into the metal oxide 530b can be inhibited. Furthermore, oxidation of the conductors 542a and 542b due to excess oxygen included in the insulator 580 can be inhibited.

The insulator 545 functions as a first gate insulating film. Like the insulator 524, the insulator 545 is preferably formed using an insulator that includes excess oxygen and releases oxygen by heating.

Specifically, silicon oxide including excess oxygen, silicon oxynitride, silicon nitride oxide, silicon nitride, silicon oxide to which fluorine is added, silicon oxide to which carbon is added, silicon oxide to which carbon and nitrogen are added, or porous silicon oxide can be used. In particular, silicon oxide and silicon oxynitride are preferable because they are thermally stable.

When an insulator including excess oxygen is provided as the insulator 545, oxygen can be effectively supplied from the insulator 545 to the channel formation region of the metal oxide 530b. Furthermore, as in the insulator 524, the concentration of impurities such as water or hydrogen in the insulator 545 is preferably reduced. The thickness of the insulator 545 is preferably greater than or equal to 1 nm and less than or equal to 20 nm.

Furthermore, to efficiently supply excess oxygen included in the insulator 545 to the metal oxide 530, a metal oxide may be provided between the insulator 545 and the conductor 560. The metal oxide preferably inhibits diffusion of oxygen from the insulator 545 to the conductor 560. Providing the metal oxide that inhibits diffusion of oxygen inhibits diffusion of excess oxygen from the insulator 545 to the conductor 560. That is, a reduction in the amount of excess oxygen supplied to the metal oxide 530 can be inhibited. Moreover, oxidation of the conductor 560 due to excess oxygen can be inhibited. For the metal oxide, a material that can be used for the insulator 544 is used.

Note that the insulator 545 may have a stacked-layer structure like the second gate insulating film. As miniaturization and high integration of transistors progress, a problem such as off-state current might arise because of a thinner gate insulating film. For that reason, when the insulator functioning as the gate insulating film has a stacked-layer structure of a high-k material and a thermally stable material, a gate potential during transistor operation can be reduced while the physical thickness is maintained. Furthermore, the stacked-layer structure can be thermally stable and have high relative permittivity.

Although the conductor 560 that functions as the first gate electrode and has a two-layer structure is illustrated in FIG. 8A and FIG. 8B, a single-layer structure or a stacked-layer structure of three or more layers may be employed.

For the conductor 560a, it is preferable to use a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, and the like), and a copper atom. Alternatively, it is preferable to use a conductive material having a function of inhibiting diffusion of oxygen (e.g., at least one of an oxygen atom, an oxygen molecule, and the like). When the conductor 560a has a function of inhibiting diffusion of oxygen, it is possible to inhibit a reduction in conductivity of the conductor 560b due to oxidation caused by oxygen included in the insulator 545. As a conductive material having a function of inhibiting diffusion of oxygen, for example, tantalum, tantalum nitride, ruthenium, ruthenium oxide, or the like is preferably used. Alternatively, for the conductor 560a, the oxide semiconductor that can be used as the metal oxide 530 can be used. In that case, when the conductor 560b is deposited by a sputtering method, the conductor 560a can have a reduced electrical resistance value to be a conductor. Such a conductor can be referred to as an OC (Oxide Conductor) electrode.

In addition, a conductive material including tungsten, copper, or aluminum as its main component is preferably used for the conductor 560b. Furthermore, the conductor 560b also functions as a wiring and thus a conductor having high conductivity is preferably used. For example, a conductive material including tungsten, copper, or aluminum as its main component can be used. Moreover, the conductor 560b may have a stacked-layer structure, for example, a stacked-layer structure of the above conductive material and titanium or titanium nitride.

The insulator 580 is provided over the conductor 542a and the conductor 542b with the insulator 544 therebetween. The insulator 580 preferably includes an excess-oxygen region. For example, the insulator 580 preferably includes silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, resin, or the like. In particular, silicon oxide and silicon oxynitride are preferable because they are thermally stable. In particular, silicon oxide and porous silicon oxide are preferable because an excess-oxygen region can be easily formed in a later step.

The insulator 580 preferably includes an excess-oxygen region. When the insulator 580 that releases oxygen by heating is provided, oxygen in the insulator 580 can be efficiently supplied to the metal oxide 530. Note that the concentration of impurities such as water or hydrogen in the insulator 580 is preferably reduced.

The opening portion of the insulator 580 is formed to overlap with the region between the conductor 542a and the conductor 542b. Accordingly, the conductor 560 is formed to be embedded in the opening portion of the insulator 580 and the region between the conductor 542a and the conductor 542b.

The gate length needs to be short for miniaturization of the semiconductor device, but it is necessary to prevent a reduction in conductivity of the conductor 560. When the conductor 560 is made thick to achieve this, the conductor 560 might have a shape with a high aspect ratio. In this embodiment, the conductor 560 is provided to be embedded in the opening portion of the insulator 580; thus, even when the conductor 560 has a shape with a high aspect ratio, the conductor 560 can be formed without collapsing during the process.

The insulator 574 is preferably provided in contact with the top surface of the insulator 580, the top surface of the conductor 560, and the top surface of the insulator 545. When the insulator 574 is deposited by a sputtering method, excess-oxygen regions can be provided in the insulator 545 and the insulator 580. Accordingly, oxygen can be supplied from the excess-oxygen regions to the metal oxide 530.

For example, a metal oxide including one kind or two or more kinds selected from hafnium, aluminum, gallium, yttrium, zirconium, tungsten, titanium, tantalum, nickel, germanium, magnesium, and the like can be used as the insulator 574.

In particular, aluminum oxide has a high barrier property, and even a thin aluminum oxide film having a thickness of greater than or equal to 0.5 nm and less than or equal to 3.0 nm can inhibit diffusion of hydrogen and nitrogen. Accordingly, aluminum oxide deposited by a sputtering method serves as an oxygen supply source and can also have a function of a barrier film against impurities such as hydrogen.

In addition, an insulator 581 functioning as an interlayer film is preferably provided over the insulator 574. As in the insulator 524 or the like, the concentration of impurities such as water or hydrogen in the insulator 581 is preferably reduced.

Furthermore, a conductor 540a and a conductor 540b are positioned in opening portions formed in the insulator 581, the insulator 574, the insulator 580, and the insulator 544. The conductor 540a and the conductor 540b are provided to face each other with the conductor 560 therebetween. The structures of the conductor 540a and the conductor 540b are similar to those of a conductor 546 and a conductor 548 that will be described later.

An insulator 582 is provided over the insulator 581. A substance having a barrier property against oxygen, hydrogen, or the like is preferably used for the insulator 582. Therefore, a material similar to that for the insulator 514 can be used for the insulator 582. For the insulator 582, a metal oxide such as aluminum oxide, hafnium oxide, or tantalum oxide is preferably used, for example.

In particular, aluminum oxide has an excellent blocking effect that prevents the passage of both oxygen and impurities such as hydrogen and moisture which are factors of fluctuation in electrical characteristics of the transistor. Accordingly, aluminum oxide can prevent mixing of impurities such as hydrogen and moisture into the transistor 500 during and after the manufacturing process of the transistor. In addition, release of oxygen from the oxide included in the transistor 500 can be inhibited. Therefore, aluminum oxide is suitably used for the protective film of the transistor 500.

In addition, an insulator 586 is provided over the insulator 582. For the insulator 586, a material similar to that for the insulator 320 can be used. Furthermore, when a material with comparatively low permittivity is used for these insulators, parasitic capacitance between wirings can be reduced. A silicon oxide film, a silicon oxynitride film, or the like can be used for the insulator 586, for example.

Furthermore, the conductor 546, the conductor 548, and the like are embedded in the insulator 520, the insulator 522, the insulator 524, the insulator 544, the insulator 580, the insulator 574, the insulator 581, the insulator 582, and the insulator 586.

The conductor 546 and the conductor 548 have functions of plugs or wirings that are connected to the capacitor 600, the transistor 500, or the transistor 550. The conductor 546 and the conductor 548 can be provided using materials similar to those for the conductor 328 and the conductor 330.

In addition, after the transistor 500 is formed, an opening portion may be formed to surround the transistor 500 and an insulator having a high barrier property against hydrogen or water may be formed to cover the opening portion. Surrounding the transistor 500 by the insulator having a high barrier property can prevent entry of moisture and hydrogen from the outside. Alternatively, a plurality of transistors 500 may be collectively surrounded by the insulator having a high barrier property against hydrogen or water. Note that when an opening portion is formed to surround the transistor 500, for example, formation of an opening portion reaching the insulator 522 or the insulator 514 and formation of the insulator having a high barrier property to be in contact with the insulator 522 or the insulator 514 are suitable because these formation steps can also serve as some of the manufacturing steps of the transistor 500. Note that the insulator having a high barrier property against hydrogen or water is formed using a material similar to that for the insulator 522 or the insulator 514, for example.

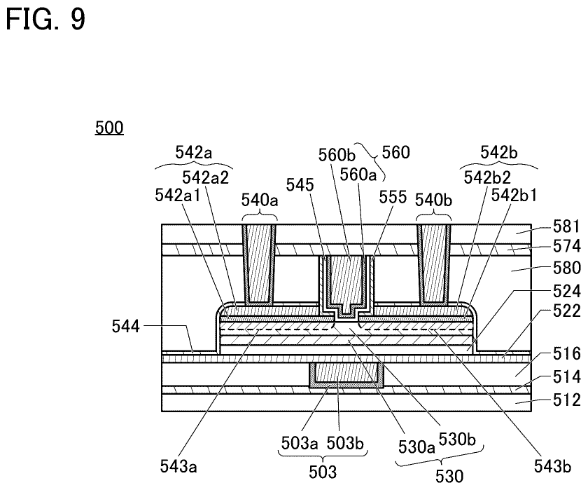

Note that the transistors that can be used in the present invention are not limited to the transistor 500 illustrated in FIG. 8A and FIG. 8B. For example, the transistor 500 having a structure illustrated in FIG. 9 may be used. The transistor 500 illustrated in FIG. 9 differs from the transistor illustrated in FIG. 8A and FIG. 8B in that an insulator 555 is used and that the conductor 542a and the conductor 542b have a stacked-layer structure of a conductor 542al and a conductor 542a2 and a stacked-layer structure of a conductor 542b1 and a conductor 542b2, respectively.

The conductor 542a has a stacked-layer structure of the conductor 542al and the conductor 542a2 over the conductor 542a1, and the conductor 542b has a stacked-layer structure of the conductor 542b1 and the conductor 542b2 over the conductor 542b1. The conductor 542a1 and the conductor 542b1 that are in contact with the metal oxide 530b are preferably conductors that are not easily oxidized, such as metal nitride. This can prevent excessive oxidation of the conductor 542a and the conductor 542b by oxygen included in the metal oxide 530b. In addition, the conductor 542a2 and the conductor 542b2 are preferably conductors that have higher conductivity than the conductor 542al and the conductor 542b1, such as metal layers. This allows the conductor 542a and the conductor 542b to function as wirings or electrodes having high conductivity. In this manner, it is possible to provide a semiconductor device where the conductor 542a and the conductor 542b that function as wirings or electrodes are provided in contact with the top surface of the metal oxide 530 that functions as an active layer.

A metal nitride is preferably used for the conductors 542al and 542b1. For example, a nitride including tantalum, a nitride including titanium, a nitride including molybdenum, a nitride including tungsten, a nitride including tantalum and aluminum, a nitride including titanium and aluminum, or the like is preferably used. In one embodiment of the present invention, a nitride including tantalum is particularly preferable. Alternatively, for example, ruthenium, ruthenium oxide, ruthenium nitride, an oxide including strontium and ruthenium, an oxide including lanthanum and nickel, or the like may be used. These materials are preferable because they are conductive materials that are not easily oxidized or materials that keep their conductivity even when absorbing oxygen.

In addition, the conductor 542a2 and the conductor 542b2 preferably have higher conductivity than the conductor 542al and the conductor 542b1. For example, the thicknesses of the conductor 542a2 and the conductor 542b2 are preferably larger than the thicknesses of the conductor 542al and the conductor 542b1. As each of the conductor 542a2 and the conductor 542b2, a conductor that can be used as the conductor 560b is used. With such a structure, resistance of the conductor 542a2 and the conductor 542b2 can be reduced.

For example, tantalum nitride or titanium nitride can be used for the conductor 542al and the conductor 542b1, and tungsten can be used for the conductor 542a2 and the conductor 542b2.

As illustrated in FIG. 9, in a cross-sectional view in the channel length direction of the transistor 500, the distance between the conductor 542al and the conductor 542b1 is shorter than the distance between the conductor 542a2 and the conductor 542b2. With such a structure, the distance between a source and a drain can be further shortened, which can shorten channel length. Thus, the frequency characteristics of the transistor 500 can be improved. Through miniaturization of the semiconductor device in this manner, a semiconductor device with higher operating speed can be provided.

The insulator 555 is preferably an insulator that is not easily oxidized, such as a nitride. The insulator 555 is formed in contact with the side surface of the conductor 542a2 and the side surface of the conductor 542b2 and has a function of protecting the conductor 542a2 and the conductor 542b2. The insulator 555 is preferably an inorganic insulator that is not easily oxidized because it is exposed to an oxidizing atmosphere. In addition, the insulator 555 is preferably an inorganic insulator that does not easily oxidize the conductors 542a2 and 542b2 because it is in contact with the conductor 542a2 and the conductor 542b2. Thus, an insulating material having a barrier property against oxygen is preferably used for the insulator 555. For example, silicon nitride can be used for the insulator 555.

The transistor 500 illustrated in FIG. 9 is formed by formation of an opening portion in the insulator 580 and the insulator 544, formation of the insulator 555 in contact with sidewalls of the opening portion, and division of the conductor 542al and the conductor 542b1 with the use of a mask. Here, the opening portion overlaps with a region between the conductor 542a2 and the conductor 542b2. In addition, parts of the conductor 542a1 and the conductor 542b1 are formed to protrude inside the opening portion. Thus, the insulator 555 is in contact with, in the opening portion, the top surface of the conductor 542al, the top surface of the conductor 542b1, the side surface of the conductor 542a2, and the side surface of the conductor 542b2. Furthermore, the insulator 545 is in contact with the top surface of the metal oxide 530 in a region between the conductor 542al and the conductor 542b1.

After the conductor 542al and the conductor 542b1 are divided, heat treatment is preferably performed in an oxygen-containing atmosphere before deposition of the insulator 545. Accordingly, oxygen can be supplied to the metal oxide 530a and the metal oxide 530b so that oxygen vacancies can be reduced. In addition, when the insulator 555 is formed in contact with the side surface of the conductor 542a2 and the side surface of the conductor 542b2, the conductor 542a2 and the conductor 542b2 can be prevented from being excessively oxidized. Consequently, electrical characteristics and reliability of the transistor can be improved. Furthermore, variation in electrical characteristics of a plurality of transistors formed over the same substrate can be suppressed.

In addition, in the transistor 500, as illustrated in FIG. 9, the insulator 524 may be formed into an island shape. Here, the insulator 524 may be formed to have a side end portion that is substantially aligned with a side end portion of the metal oxide 530.

In addition, in the transistor 500, as illustrated in FIG. 9, a structure may be employed in which the insulator 522 is in contact with the insulator 516 and the conductor 503. In other words, a structure may be employed in which the insulator 520 illustrated in FIG. 8A and FIG. 8B is not provided.

Next, the capacitor 600 is provided above the transistor 500. The capacitor 600 includes a conductor 610, a conductor 620, and an insulator 630.

In addition, a conductor 612 may be provided over the conductor 546 and the conductor 548. The conductor 612 has a function of a plug or a wiring that is connected to the transistor 500. The conductor 610 has a function of an electrode of the capacitor 600. Note that the conductor 612 and the conductor 610 can be formed at the same time.

For the conductor 612 and the conductor 610, a metal film including an element selected from molybdenum, titanium, tantalum, tungsten, aluminum, copper, chromium, neodymium, and scandium; a metal nitride film including the above element as its component (a tantalum nitride film, a titanium nitride film, a molybdenum nitride film, or a tungsten nitride film); or the like can be used. Alternatively, it is possible to employ a conductive material such as indium tin oxide, indium oxide including tungsten oxide, indium zinc oxide including tungsten oxide, indium oxide including titanium oxide, indium tin oxide including titanium oxide, indium zinc oxide, or indium tin oxide to which silicon oxide is added.

Although the conductor 612 and the conductor 610 each having a single-layer structure are illustrated in this embodiment, the structure is not limited thereto; a stacked-layer structure of two or more layers may be employed. For example, between a conductor having a barrier property and a conductor having high conductivity, a conductor that is highly adhesive to the conductor having a barrier property and the conductor having high conductivity may be formed.

The conductor 620 is provided to overlap with the conductor 610 with the insulator 630 therebetween. Note that a conductive material such as a metal material, an alloy material, or a metal oxide material can be used for the conductor 620. It is preferable to use a high-melting-point material that has both heat resistance and conductivity, such as tungsten or molybdenum, and it is particularly preferable to use tungsten. In the case where the conductor 620 is formed at the same time as another component such as a conductor, copper (Cu), aluminum (Al), or the like, which is a low-resistance metal material, may be used.

An insulator 640 is provided over the conductor 620 and the insulator 630. The insulator 640 can be provided using a material similar to that for the insulator 320. In addition, the insulator 640 may function as a planarization film that covers an uneven shape therebelow.

With the use of this structure, a semiconductor device using a transistor including an oxide semiconductor can be miniaturized or highly integrated.

As a substrate that can be used for the semiconductor device according to one embodiment of the present invention, a glass substrate, a quartz substrate, a sapphire substrate, a ceramic substrate, a metal substrate (e.g., a stainless steel substrate, a substrate including stainless steel foil, a tungsten substrate, a substrate including tungsten foil, or the like), a semiconductor substrate (e.g., a single crystal semiconductor substrate, a polycrystalline semiconductor substrate, a compound semiconductor substrate, or the like), an SOI (silicon on Insulator) substrate, or the like can be used. Alternatively, a plastic substrate having heat resistance to processing temperature in this embodiment may be used. Examples of the glass substrate include barium borosilicate glass, aluminosilicate glass, aluminoborosilicate glass, and soda lime glass. Alternatively, crystallized glass or the like can be used.

Alternatively, a flexible substrate; an attachment film; paper or a base film including a fibrous material; or the like can be used as the substrate. As examples of the flexible substrate, the attachment film, the base material film, and the like, the following can be given. Examples include plastics typified by polyethylene terephthalate (PET), polyethylene naphthalate (PEN), polyether sulfone (PES), and polytetrafluoroethylene (PTFE). Another example is a synthetic resin such as acrylic. Other examples include polypropylene, polyester, polyvinyl fluoride, and polyvinyl chloride. Other examples include polyamide, polyimide, an aramid resin, an epoxy resin, an inorganic evaporated film, and paper. In particular, the use of a semiconductor substrate, a single crystal substrate, an SOI substrate, or the like for the manufacture of transistors enables the manufacture of small-sized transistors with a small variation in characteristics, size, shape, or the like and high current capability. When a circuit is formed with such transistors, lower power consumption of the circuit or higher integration of the circuit can be achieved.

Alternatively, a flexible substrate may be used as the substrate, and a transistor, a resistor, a capacitor, and/or the like may be formed directly on the flexible substrate. Alternatively, a separation layer may be provided between the substrate and the transistor, the resistor, the capacitor, and/or the like. After part or the whole of a semiconductor device is completed over the separation layer, the separation layer can be used for separation from the substrate and transfer to another substrate. In such a case, the transistor, the resistor, the capacitor, and/or the like can be transferred to a substrate having low heat resistance or a flexible substrate. Note that as the separation layer, a stacked-layer structure of a tungsten film and a silicon oxide film that are inorganic films, a structure where an organic resin film of polyimide or the like is formed over a substrate, a silicon film including hydrogen, or the like can be used, for example.

That is, a semiconductor device may be formed over one substrate and then transferred to another substrate. Examples of a substrate to which a semiconductor device is transferred include, in addition to the above substrates over which transistors can be formed, a paper substrate, a cellophane substrate, an aramid film substrate, a polyimide film substrate, a stone substrate, a wood substrate, a cloth substrate (including a natural fiber (silk, cotton, or hemp), a synthetic fiber (nylon, polyurethane, or polyester), a regenerated fiber (acetate, cupro, rayon, or regenerated polyester), or the like), a leather substrate, and a rubber substrate. With the use of these substrates, the manufacture of a flexible semiconductor device, the manufacture of a robust semiconductor device, provision of high heat resistance, a reduction in weight, or a reduction in thickness can be achieved.

Providing a semiconductor device over a flexible substrate can inhibit an increase in weight and can provide a robust semiconductor device.

Note that the transistor 550 illustrated in FIG. 7 is an example and the structure is not limited thereto; an appropriate transistor is used in accordance with a circuit structure, a driving method, or the like. For example, when the semiconductor device is a single-polarity circuit that is composed of only OS transistors (which means transistors having the same polarity, e.g., only n-channel transistors), the transistor 550 has a structure similar to that of the transistor 500.

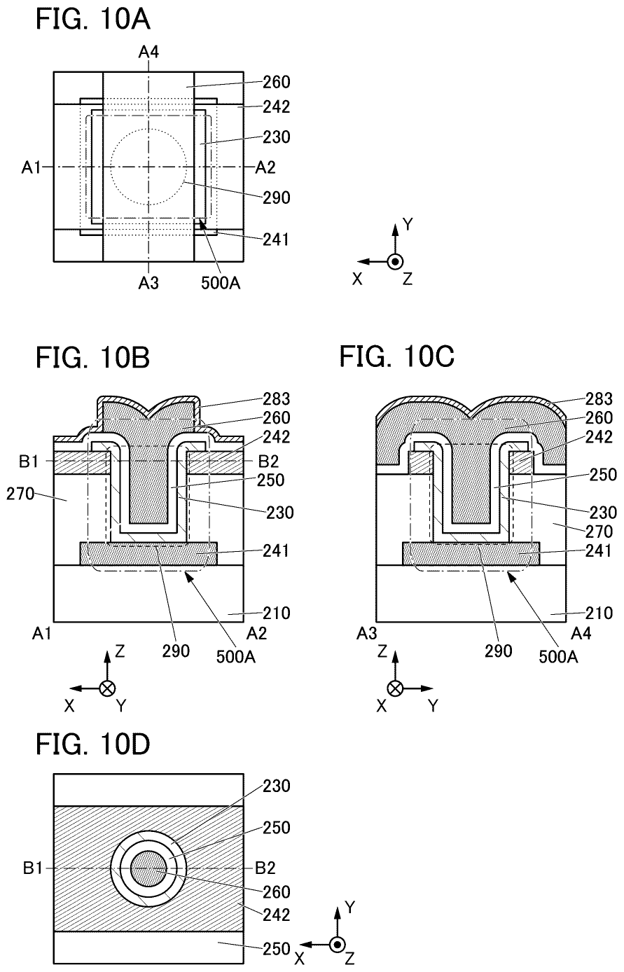

Note that the transistors that can be used in the present invention are not limited to the transistors 500 illustrated in FIG. 8A, FIG. 8B, and FIG. 9. For example, a transistor 500A having structures illustrated in FIG. 10A to FIG. 10D may be used. The transistor 500A illustrated in FIG. 10A to FIG. 10D differs from the transistors illustrated in FIG. 8A, FIG. 8B, and FIG. 9 in that the transistor 500A is a vertical channel type transistor.

FIG. 10A to FIG. 10D are top views and cross-sectional views each illustrating a transistor structure example. FIG. 10A is a top view of the transistor 500A. FIG. 10B is a cross-sectional view of a portion indicated by a dashed-dotted line A1-A2 in FIG. 10A, and FIG. 10C is a cross-sectional view of a portion indicated by a dashed-dotted line A3-A4 in FIG. 10A. FIG. 10D is a top view of a portion indicated by a dashed-dotted line B1-B2 in FIG. 10B. Note that in the top views of FIG. 10A and FIG. 10D, some components are omitted for clarity of the drawings.

The transistor 500A includes a conductor 241 and an insulator 270 over an insulator 210, a metal oxide 230 over the conductor 241, an insulator 250 over the metal oxide 230, a conductor 260 over the insulator 250, and a conductor 242 over the insulator 270.

The conductor 241 includes a region that functions as one of a source electrode and a drain electrode of the transistor 500A. The conductor 242 includes a region that functions as the other of the source electrode and the drain electrode of the transistor 500A. The conductor 260 includes a region that functions as a gate electrode of the transistor 500A. The metal oxide 230 includes a region that functions as a channel formation region.

For the metal oxide 230, each of the materials described as the metal oxide 530a and the metal oxide 530b can be used.

The metal oxide 230 includes the channel formation region, and a source region and a drain region that are provided to sandwich the channel formation region in the transistor 500A. At least part of the channel formation region overlaps with the conductor 260. The source region overlaps with one of the conductor 241 and the conductor 242, and the drain region overlaps with the other of the conductor 241 and the conductor 242.

An opening portion that reaches the conductor 241 is provided in the conductor 242 and the insulator 270. In addition, the opening portion includes a region that overlaps with the conductor 241 in the top view. Furthermore, at least parts of the metal oxide 230, the insulator 250, and the conductor 260 are placed in the opening portion. Note that it can be said that the opening portion includes an opening portion included in the conductor 242 and an opening portion included in the insulator 270. Moreover, it can be said that the conductor 242 includes an opening portion that overlaps with the conductor 241 in the top view.

The metal oxide 230 is provided in contact with the side surface and the bottom surface of the opening portion 290 provided in the conductor 242 and the insulator 270. In other words, the metal oxide 230 includes regions that are in contact with the side surface of the opening portion 290 included in the conductor 242 and the top surfaces of the conductors 241 and 242. In addition, the metal oxide 230 includes a depressed portion. The depressed portion includes a region that overlaps with the opening portion 290 included in the conductor 242 in the top view.

At least part of the insulator 250 is provided in the depressed portion of the metal oxide 230. In addition, the insulator 250 includes a region that is in contact with the top surface of the metal oxide 230. Furthermore, the insulator 250 includes a depressed portion. The depressed portion is positioned inside the depressed portion of the metal oxide 230.

The conductor 260 is provided to fill the depressed portion of the insulator 250. In addition, the conductor 260 includes a region that is in contact with the top surface of the insulator 250. Furthermore, the conductor 260 includes a region that overlaps with the metal oxide 230 with the insulator 250 therebetween in a region between the conductor 241 and the conductor 242 in the cross-sectional view. Note that the conductor 260 whose bottom shape is a needle-like shape may be referred to as a needle-like gate.

In the above structure, channel length of the transistor 500A is the distance from the top surface of the conductor 241 to the bottom surface of the conductor 242 in the cross-sectional view. That is, the channel length of the transistor 500A can be adjusted by thickness of the insulator 270 in the region that overlaps with the conductor 241. For example, a reduction in the thickness of the insulator 270 enables manufacture of the transistor 500A with shorter channel length.

In addition, in the above structure, channel width of the transistor 500A is length of a region where the insulator 270 and the metal oxide 230 are in contact with each other in the top view and is also length of the outline (outer circumference) of the metal oxide 230 in the top view. That is, the channel width of the transistor 500A can be adjusted by the diameter of an opening portion provided in the insulator 270. For example, an increase in the diameter of the opening portion enables manufacture of the transistor 500A with larger channel width. Note that the opening portion can be rephrased as an opening portion provided with some components of the transistor 500A (here, the metal oxide 230, the insulator 250, and the conductor 260).

The transistor 500A has a structure where the channel formation region surrounds the gate electrode. Thus, it can be said that the transistor 500A is a transistor having a CAA (Channel-All-Around) structure.

Note that although FIG. 10D illustrates a structure where a top surface shape of the opening portion included in the conductor 242 has a circular shape, the present invention is not limited thereto. For example, the top surface shape of the opening portion included in the conductor 242 may be an elliptical shape, a polygonal shape, or a polygonal shape with rounded corners. Here, the polygonal shape refers to a triangle, a rectangle, a pentagon, a hexagon, or the like.

The insulator 250 may have either a single-layer structure or a stacked-layer structure.

For example, silicon oxide, silicon oxynitride, silicon oxide to which fluorine is added, silicon oxide to which carbon is added, silicon oxide to which carbon and nitrogen are added, porous silicon oxide, or the like can be used for the insulator 250. In particular, silicon oxide and silicon oxynitride are preferable because they are thermally stable. In that case, the insulator 250 is an insulator that includes at least oxygen and silicon.

The concentration of impurities such as water and hydrogen in the insulator 250 is preferably reduced.

Note that an insulator having a barrier property against oxygen may be provided between the insulator 250 and the metal oxide 230. The insulator is provided in contact with the bottom surface of the insulator 250 and the depressed portion of the metal oxide 230. When the insulator has a barrier property against oxygen, oxygen included in the insulator 250 can be supplied to the channel formation region, which can inhibit excessive supply of oxygen included in the insulator 250 to the channel formation region. Thus, when heat treatment or the like is performed, release of oxygen from the metal oxide 230 can be inhibited, which can inhibit formation of oxygen vacancies in the metal oxide 230. Accordingly, the transistor 500A can have favorable electrical characteristics and higher reliability.

An insulator including an oxide of one or both aluminum and hafnium is preferably used as the insulator. Aluminum oxide, hafnium oxide, an oxide including aluminum and hafnium (hafnium aluminate), an oxide including hafnium and silicon (hafnium silicate), or the like can be used for the insulator. Aluminum oxide is further preferably used for the insulator. In that case, the insulator is an insulator that includes at least oxygen and aluminum. Note that the insulator, for example, does not easily transmit oxygen compared with the insulator 250. In addition, for example, a material that does not easily transmit oxygen compared with the insulator 250 is used for the insulator. For example, magnesium oxide, gallium oxide, gallium zinc oxide, indium gallium zinc oxide, or the like may be used for the insulator.

FIG. 10B illustrates a single-layer structure of the conductor 260. Note that the conductor 260 may have a stacked-layer structure. For example, the conductor 260 preferably includes a first conductor and a second conductor over the first conductor. Specifically, the first conductor of the conductor 260 is preferably placed to cover the bottom surface and side surfaces of the second conductor of the conductor 260.

For the first conductor of the conductor 260, it is preferable to use a conductive material having a function of inhibiting diffusion of impurities such as a hydrogen atom, a hydrogen molecule, a water molecule, a nitrogen atom, a nitrogen molecule, a nitrogen oxide molecule, and a copper atom. Alternatively, it is preferable to use a conductive material having a function of inhibiting diffusion of oxygen (e.g., at least one of an oxygen atom, an oxygen molecule, and the like). Alternatively, it is preferable to use a conductive material that is not easily oxidized.

When the first conductor of the conductor 260 has a function of inhibiting diffusion of oxygen, for example, it is possible to inhibit a decrease in conductivity due to oxidation of the second conductor of the conductor 260 by oxygen included in the insulator 250. As a conductive material having a function of inhibiting diffusion of oxygen, for example, titanium, titanium nitride, tantalum, tantalum nitride, ruthenium, ruthenium oxide, or the like is preferably used.

An insulator 283 is provided over the insulator 250. An insulator having a barrier property against hydrogen is preferably used as the insulator 283. This makes it possible to inhibit diffusion of hydrogen into the metal oxide 230 from the outside of the transistor 500A through the insulator 250. Each of a silicon nitride film and a silicon nitride oxide film can be suitably used for the insulator 283 because each of the silicon nitride film and the silicon nitride oxide film releases a small amount of impurities (e.g., water and hydrogen) and has a feature of not easily transmitting oxygen and hydrogen.

The composition, structure, method, and the like described in this embodiment can be used in combination as appropriate with the compositions, structures, methods, and the like described in the other embodiments, an example, and the like.

### Embodiment 3

In this embodiment, a cross-sectional structure example of an element layer (a storage layer) including OS transistors provided over an element layer (a driver circuit layer) including stacked Si transistors, which is a structure applicable to each circuit included in a semiconductor device, is described. In this embodiment, an example of a cross-sectional schematic view applicable to a NOSRAM circuit structure is described.

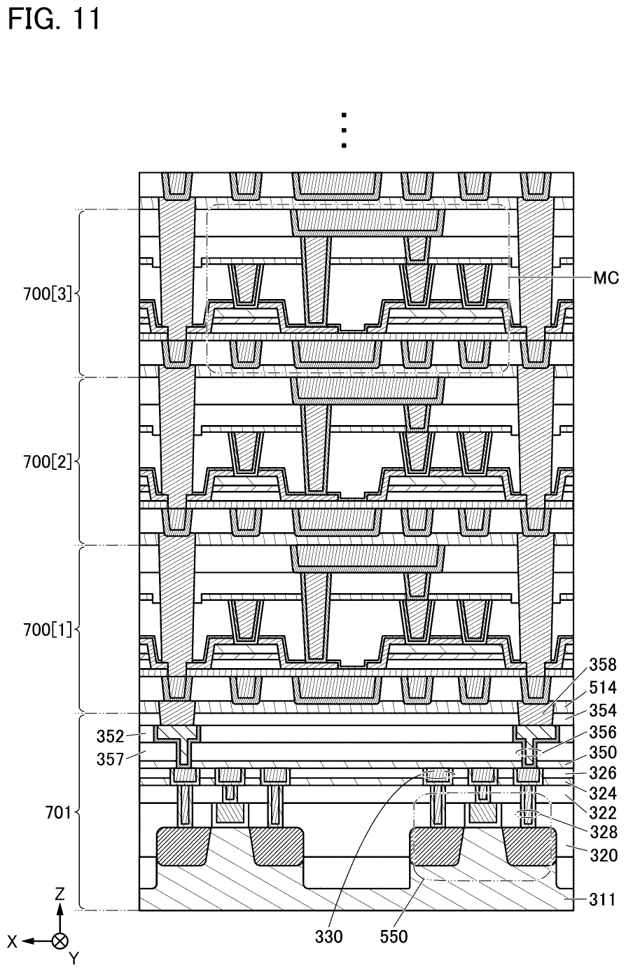

FIG. 11 illustrates a cross-sectional structure example of the case of using a NOSRAM circuit structure. In the example illustrated in FIG. 11, an element layer 700[1] to an element layer 700[3] are stacked over an element layer 701. The element layer 701 corresponds to the element layer 20 described in Embodiment 1 above, and the element layer 700 corresponds to the element layer 30.

FIG. 11 also illustrates an example of the transistor 550 included in the element layer 701. As the transistor 550, the transistor 550 described in the above embodiment can be used.

Note that the transistor 550 illustrated in FIG. 11 is an example and is not limited to the structure illustrated therein; an appropriate transistor can be used in accordance with a circuit structure or a driving method.

A wiring layer provided with an interlayer film, a wiring, a plug, and the like may be provided between the element layer 701 and the element layers 700 or between a k-th element layer 700 and a (k+1)-th element layer 700. Note that in this embodiment and the like, the k-th element layer 700 is referred to as an element layer 700[k], and the (k+1)-th element layer 700 is referred to as an element layer 700[k+1], in some cases. Here, k is an integer greater than or equal to 1 and less than or equal to N. In addition, in this embodiment and the like, the solutions of “k+α (α is an integer greater than or equal to 1)” and “k−α” are each an integer greater than or equal to 1 and less than or equal to N.

In addition, a plurality of wiring layers can be provided in accordance with design. Furthermore, in this specification and the like, a wiring and a plug connected to the wiring may be a single component. That is, part of a conductor functions as a wiring in some cases, and part of a conductor functions as a plug in other cases.

For example, the insulator 320, the insulator 322, the insulator 324, and the insulator 326 are sequentially stacked and provided over the transistor 550 as interlayer films. In addition, the conductor 328 or the like is embedded in the insulator 320 and the insulator 322. Furthermore, the conductor 330 or the like is embedded in the insulator 324 and the insulator 326. Note that the conductor 328 and the conductor 330 each function as a contact plug or a wiring.

In addition, the insulators functioning as interlayer films may also function as planarization films that cover uneven shapes therebelow. For example, the top surface of the insulator 320 may be planarized by planarization treatment using a chemical mechanical polishing (CMP) method to increase planarity.

A wiring layer may be provided over the insulator 326 and the conductor 330. For example, in FIG. 11, the insulator 350, an insulator 357, the insulator 352, and the insulator 354 are sequentially stacked and provided over the insulator 326 and the conductor 330. Furthermore, the conductor 356 is formed in the insulator 350, the insulator 357, and the insulator 352. The conductor 356 functions as a contact plug or a wiring.

The insulator 514 included in the element layer 700[1] is provided over the insulator 354. In addition, a conductor 358 is embedded in the insulator 514 and the insulator 354. The conductor 358 functions as a contact plug or a wiring. For example, the wiring WBL (or the wiring RBL) and the transistor 550 are electrically connected through the conductor 358, the conductor 356, the conductor 330, and the like.

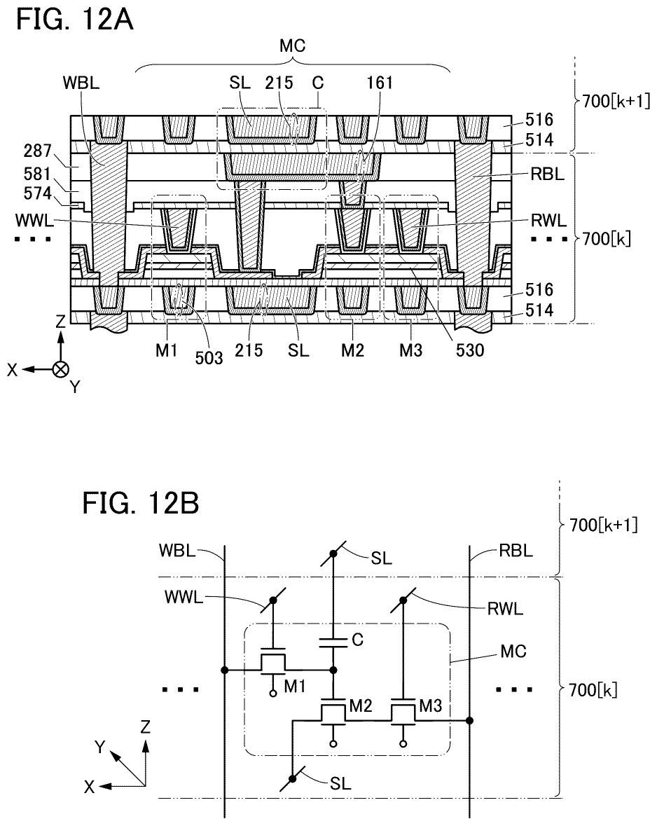

FIG. 12A illustrates a cross-sectional structure example of the element layer 700[k]. In addition, FIG. 12B illustrates an equivalent circuit diagram of FIG. 12A.

The memory cells MC illustrated in FIG. 11 and FIG. 12A each include the transistor M1, the transistor M2, and the transistor M3 over the insulator 514. In addition, a conductor 215 is provided over the insulator 514. The conductor 215 can be formed using the same material in the same process as those of the conductor 503 at the same time.

In addition, the transistor M2 and the transistor M3 illustrated in FIG. 11 and FIG. 12A share one island-shaped metal oxide 530. In other words, part of the one island-shaped metal oxide 530 functions as a channel formation region of the transistor M2, and another part thereof functions as a channel formation region of the transistor M3. Furthermore, the source of the transistor M2 and a drain of the transistor M3 are shared, or the drain of the transistor M2 and a source of the transistor M3 are shared. Thus, the area occupied by the transistor M2 and the transistor M3 is smaller than that of the case where the transistor M2 and the transistor M3 are independently provided.

In addition, in each of the memory cells MC illustrated in FIG. 11 and FIG. 12A, an insulator 287 is provided over the insulator 581, and a conductor 161 is embedded in the insulator 287. Furthermore, the insulator 514 of the element layer 700[k+1] is provided over the insulator 287 and the conductor 161.

In FIG. 11 and FIG. 12A, the conductor 215 of the element layer 700[k+1] functions as one terminal of the capacitor C, the insulator 514 of the element layer 700[k+1] functions as a dielectric of the capacitor C, and the conductor 161 functions as the other terminal of the capacitor C. Furthermore, the other of a source and a drain of the transistor MI is connected to the conductor 161 through a contact plug, and the gate of the transistor M2 is connected to the conductor 161 through another contact plug.

This embodiment can be implemented in combination with the other embodiments described in this specification as appropriate.

### Embodiment 4

A semiconductor device 900 of one embodiment of the present invention is described in this embodiment. The semiconductor device 900 can function as a storage device.

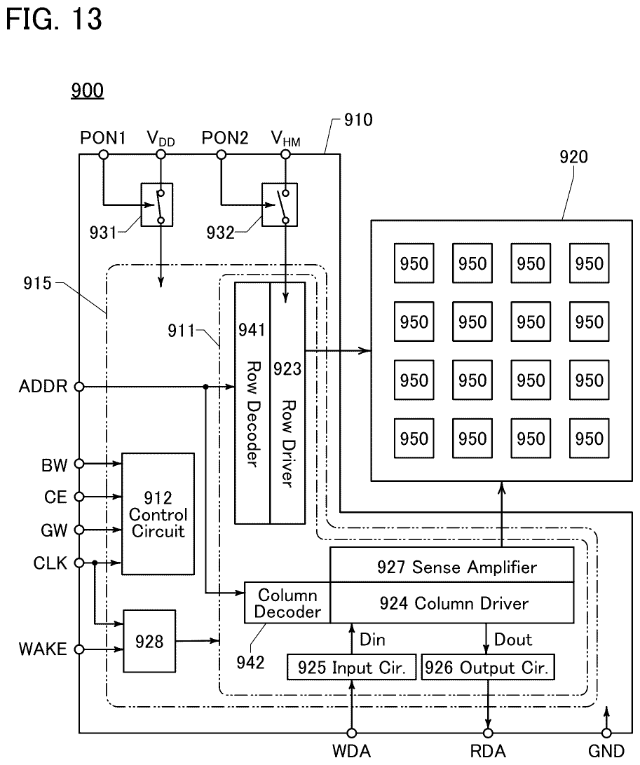

FIG. 13 is a block diagram illustrating a structure example of the semiconductor device 900. The semiconductor device 900 illustrated in FIG. 13 includes a driver circuit 910 and a memory array 920. The memory array 920 includes one or more memory cells 950. FIG. 13 illustrates an example where the memory array 920 includes a plurality of memory cells 950 arranged in a matrix.

The memory cell 32 or the like illustrated as an example in the above embodiment can be employed for the memory cell 950.

The driver circuit 910 includes a PSW 931 (a power switch), a PSW 932, and a peripheral circuit 915. The peripheral circuit 915 includes a peripheral circuit 911, a control circuit 912 (Control Circuit), and a voltage generation circuit 928.

In the semiconductor device 900, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 912.

The control circuit 912 is a logic circuit having a function of controlling the overall operation of the semiconductor device 900. For example, the control circuit 912 performs logical operation on the signal CE, the signal GW, and the signal BW to determine an operation mode of the semiconductor device 900 (e.g., write operation or read operation). Alternatively, the control circuit 912 generates a control signal for the peripheral circuit 911 so that the operation mode is executed.

The voltage generation circuit 928 has a function of generating a negative voltage. The signal WAKE has a function of controlling the input of the signal CLK to the voltage generation circuit 928. For example, when an H-level signal is supplied as the signal WAKE, the signal CLK is input to the voltage generation circuit 928, and the voltage generation circuit 928 generates a negative voltage.

The peripheral circuit 911 is a circuit for writing and reading data to/from the memory cell 950. The peripheral circuit 911 includes a row decoder 941 (Row Decoder), a column decoder 942 (Column Decoder), a row driver 923 (Row Driver), a column driver 924 (Column Driver), an input circuit 925 (Input Cir.), an output circuit 926 (Output Cir.), and a sense amplifier 927 (Sense Amplifier).

The row decoder 941 and the column decoder 942 have a function of decoding the signal ADDR. The row decoder 941 is a circuit for specifying a row to be accessed, and the column decoder 942 is a circuit for specifying a column to be accessed. The row driver 923 has a function of selecting a row specified by the row decoder 941. The column driver 924 has a function of writing data to the memory cell 950, a function of reading data from the memory cell 950, a function of retaining the read data, and the like.

The input circuit 925 has a function of retaining the signal WDA. Data retained by the input circuit 925 is output to the column driver 924. Data output from the input circuit 925 is data (Din) to be written to the memory cell 950. Data (Dout) read from the memory cell 950 by the column driver 924 is output to the output circuit 926. The output circuit 926 has a function of retaining Dout. In addition, the output circuit 926 has a function of outputting Dout to the outside of the semiconductor device 900. Data output from the output circuit 926 is the signal RDA.

The PSW 931 has a function of controlling the supply of V_{DD} to the peripheral circuit 915. The PSW 932 has a function of controlling the supply of V_{HM} to the row driver 923. Here, in the semiconductor device 900, a high power supply voltage is V_{DD} and a low power supply voltage is GND (a ground potential). In addition, V_{HM} is a high power supply voltage used to set a word line at a high level and is higher than V_{DD}. The ON/OFF of the PSW 931 is controlled by the signal PON1, and the ON/OFF of the PSW 932 is controlled by the signal PON2. The number of power domains to which V_{DD} is supplied is one in the peripheral circuit 915 in FIG. 13 but can be more than one. In that case, a power switch is provided for each power domain.

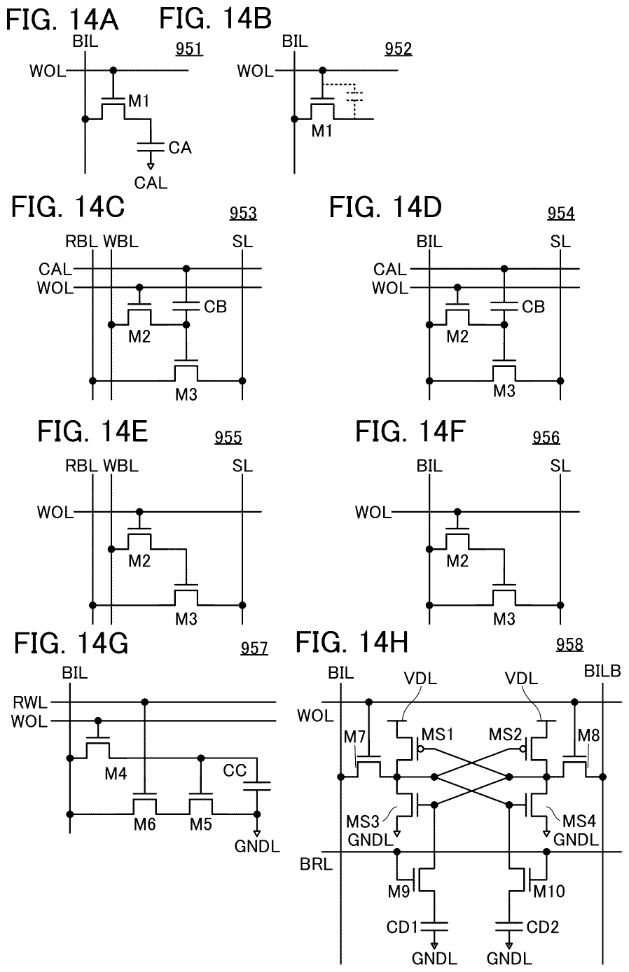

Structure examples of other memory cells that can be employed as the memory cell 950 are described using FIG. 14A to FIG. 14H.

### DOSRAM

FIG. 14A illustrates a circuit structure example of a DRAM memory cell. In this specification and the like, a DRAM using an OS transistor is referred to as a DOSRAM (Dynamic Oxide Semiconductor Random Access Memory). A memory cell 951 includes a transistor M1 and a capacitor CA.

Note that the transistor M1 may include a front gate (simply referred to as a gate in some cases) and a back gate. Here, the back gate may be connected to a wiring supplied with a constant potential or a signal, and the front gate and the back gate may be connected.

A first terminal of the transistor M1 is connected to a first terminal of the capacitor CA. A second terminal of the transistor M1 is connected to a wiring BIL. A gate of the transistor M1 is connected to a wiring WOL. A second terminal of the capacitor CA is connected to a wiring CAL.

The wiring BIL functions as a bit line, and the wiring WOL functions as a word line. The wiring CAL functions as a wiring for applying a predetermined potential to the second terminal of the capacitor CA. In data writing and reading, a low-level potential (referred to as a reference potential in some cases) is preferably applied to the wiring CAL.

Data writing and reading are performed in such a manner that a high-level potential is applied to the wiring WOL to turn on the transistor M1 so that the wiring BIL and the first terminal of the capacitor CA are brought into a conduction state (a state where current can flow therethrough).

The memory cell that can be used as the memory cell 950 is not limited to the memory cell 951, and the circuit structure can be changed. For example, the structure of a memory cell 952 illustrated in FIG. 14B may be employed. The memory cell 952 is an example including neither the capacitor CA nor the wiring CAL. The first terminal of the transistor MI is in an electrically floating state.

In the memory cell 952, a potential written through the transistor MI is retained in a capacitor (also referred to as parasitic capacitance) between the first terminal and the gate, which is shown by a dashed line. Such a structure enables significant simplification of the structure of the memory cell.

Note that an OS transistor is preferably used as the transistor M1. An OS transistor has a characteristic of extremely low off-state current. The use of an OS transistor as the transistor M1 enables the leakage current of the transistor MI to be extremely low. That is, written data can be retained for a long time with the transistor M1, and thus the frequency of refresh of the memory cell can be decreased. Alternatively, refresh operation of the memory cell can be unnecessary. In addition, the extremely low leakage current allows multi-level data or analog data to be retained in the memory cell 951 and the memory cell 952.

### NOSRAM

FIG. 14C illustrates a circuit structure example of a gain-cell-type memory cell including two transistors and one capacitor. A memory cell 953 includes a transistor M2, a transistor M3, and a capacitor CB. In this specification and the like, a storage device including a gain-cell-type memory cell using an OS transistor as the transistor M2 is referred to as a NOSRAM (Nonvolatile Oxide Semiconductor RAM) in some cases.

A first terminal of the transistor M2 is connected to a first terminal of the capacitor CB. A second terminal of the transistor M2 is connected to a wiring WBL. A gate of the transistor M2 is connected to the wiring WOL. A second terminal of the capacitor CB is connected to the wiring CAL. A first terminal of the transistor M3 is connected to a wiring RBL. A second terminal of the transistor M3 is connected to the wiring SL. A gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. In data writing, during data retention, and in data reading, a low-level potential (referred to as a reference potential in some cases) is preferably applied to the wiring CAL.

Data writing is performed in such a manner that a high-level potential is applied to the wiring WOL to turn on the transistor M2 so that the wiring WBL and the first terminal of the capacitor CB are brought into a conduction state. Specifically, when the transistor M2 is in an on state, a potential corresponding to information to be stored is applied to the wiring WBL, and the potential is written to the first terminal of the capacitor CB and the gate of the transistor M3. Then, a low-level potential is applied to the wiring WOL to turn off the transistor M2 so that the potential of the first terminal of the capacitor CB and the potential of the gate of the transistor M3 are retained.

Data reading is performed by applying a predetermined potential to the wiring SL. Current flowing between a source and a drain of the transistor M3 and the potential of the first terminal of the transistor M3 are determined by the potential of the gate of the transistor M3 and the potential of the second terminal of the transistor M3; thus, by reading the potential of the wiring RBL connected to the first terminal of the transistor M3, the potential retained in the first terminal of the capacitor CB (or the gate of the transistor M3) can be read. In other words, information written to this memory cell can be read from the potential retained in the first terminal of the capacitor CB (or the gate of the transistor M3).

Alternatively, for example, the wiring WBL and the wiring RBL may be combined into one wiring BIL. FIG. 14D illustrates a circuit structure example of the memory cell. In a memory cell 954, one wiring BIL corresponds to the wiring WBL and the wiring RBL in the memory cell 953, and the second terminal of the transistor M2 and the first terminal of the transistor M3 are connected to the wiring BIL. In other words, one wiring BIL operates as the write bit line and the read bit line in the memory cell 954.

A memory cell 955 illustrated in FIG. 14E is an example where the capacitor CB and the wiring CAL in the memory cell 953 are omitted. A memory cell 956 illustrated in FIG. 14F is an example where the capacitor CB and the wiring CAL in the memory cell 954 are omitted. With such structures, the degree of integration of memory cells can be increased.

Note that an OS transistor is preferably used as at least the transistor M2. In particular, an OS transistor is preferably used as each of the transistor M2 and the transistor M3.

Since the OS transistor has a characteristic of extremely low off-state current, written data can be retained for a long time with the transistor M2, and thus the frequency of refresh of the memory cell can be decreased. Alternatively, refresh operation of the memory cell can be unnecessary. In addition, the extremely low leakage current allows multi-level data or analog data to be retained in the memory cell 953, the memory cell 954, the memory cell 955, and the memory cell 956.

The memory cell 953, the memory cell 954, the memory cell 955, and the memory cell 956 each employing the OS transistor as the transistor M2 are embodiments of a NOSRAM.

Note that a Si transistor may be used as the transistor M3. The Si transistor can have high field-effect mobility and can be formed as a p-channel transistor, so that circuit design flexibility can be increased.

In the case where an OS transistor is used as the transistor M3, the memory cell can be composed of a single-polarity circuit.

FIG. 14G illustrates a gain-cell-type memory cell 957 including three transistors and one capacitor. The memory cell 957 includes a transistor M4 to a transistor M6 and a capacitor CC.

A first terminal of the transistor M4 is connected to a first terminal of the capacitor CC. A second terminal of the transistor M4 is connected to the wiring BIL. A gate of the transistor M4 is connected to the wiring WOL. A second terminal of the capacitor CC is connected to a first terminal of the transistor M5 and a wiring GNDL. A second terminal of the transistor M5 is connected to a first terminal of the transistor M6, and a gate of the transistor M5 is connected to the first terminal of the capacitor CC. A second terminal of the transistor M6 is connected to the wiring BIL, and a gate of the transistor M6 is connected to a wiring RWL.

The wiring BIL functions as a bit line, the wiring WOL functions as a write word line, and the wiring RWL functions as a read word line. The wiring GNDL is a wiring for applying a low-level potential.

Data writing is performed in such a manner that a high-level potential is applied to the wiring WOL to turn on the transistor M4 so that the wiring BIL and the first terminal of the capacitor CC are brought into a conduction state. Specifically, when the transistor M4 is in an on state, a potential corresponding to information to be stored is applied to the wiring BIL, and the potential is written to the first terminal of the capacitor CC and the gate of the transistor M5. Then, a low-level potential is applied to the wiring WOL to turn off the transistor M4 so that the potential of the first terminal of the capacitor CC and the potential of the gate of the transistor M5 are retained.

Data reading is performed in such a manner that after a predetermined potential is precharged to the wiring BIL, the wiring BIL is brought into an electrically floating state, and a high-level potential is applied to the wiring RWL. Since the wiring RWL has the high-level potential, the transistor M6 is turned on, and the wiring BIL and the second terminal of the transistor M5 are brought into a conduction state. At this time, the potential of the wiring BIL is applied to the second terminal of the transistor M5; however, the potential of the second terminal of the transistor M5 and the potential of the wiring BIL are changed in accordance with the potential retained in the first terminal of the capacitor CC (or the gate of the transistor M5). Here, by reading the potential of the wiring BIL, the potential retained in the first terminal of the capacitor CC (or the gate of the transistor M5) can be read. In other words, information written to the memory cell can be read from the potential retained in the first terminal of the capacitor CC (or the gate of the transistor M5).

Note that an OS transistor is preferably used as at least the transistor M4.

Note that a Si transistor may be used as each of the transistors M5 and M6. As described above, a Si transistor has higher field-effect mobility than an OS transistor in some cases depending on the crystal state of silicon used in a semiconductor layer, for example.

In the case where OS transistors are used as the transistors M5 and M6, the memory cell can be composed of a single-polarity circuit.

### OS-SRAM

FIG. 14H illustrates an example of an SRAM (Static Random Access Memory) using an OS transistor. In this specification and the like, an SRAM using an OS transistor is referred to as an OS-SRAM (Oxide Semiconductor-SRAM). Note that a memory cell 958 illustrated in FIG. 14H is a memory cell of an SRAM capable of backup.

The memory cell 958 includes a transistor M7 to a transistor M10, a transistor MS1 to a transistor MS4, a capacitor CD1, and a capacitor CD2. Note that the transistor MS1 and the transistor MS2 are p-channel transistors, and the transistor MS3 and the transistor MS4 are n-channel transistors.

A first terminal of the transistor M7 is connected to the wiring BIL, and a second terminal of the transistor M7 is connected to a first terminal of the transistor MS1, a first terminal of the transistor MS3, a gate of the transistor MS2, a gate of the transistor MS4, and a first terminal of the transistor M10. A gate of the transistor M7 is connected to the wiring WOL. A first terminal of the transistor M8 is connected to a wiring BILB, and a second terminal of the transistor M8 is connected to a first terminal of the transistor MS2, a first terminal of the transistor MS4, a gate of the transistor MS1, a gate of the transistor MS3, and a first terminal of the transistor M9. A gate of the transistor M8 is connected to the wiring WOL.

A second terminal of the transistor MS1 is connected to a wiring VDL. A second terminal of the transistor MS2 is connected to the wiring VDL. A second terminal of the transistor MS3 is connected to the wiring GNDL. A second terminal of the transistor MS4 is connected to the wiring GNDL.

A second terminal of the transistor M9 is connected to a first terminal of the capacitor CD1, and a gate of the transistor M9 is connected to the wiring BRL. A second terminal of the transistor M10 is connected to a first terminal of the capacitor CD2, and a gate of the transistor M10 is connected to the wiring BRL.

A second terminal of the capacitor CD1 is connected to the wiring GNDL, and a second terminal of the capacitor CD2 is connected to the wiring GNDL.

The wiring BIL and the wiring BILB each function as a bit line, the wiring WOL functions as a word line, and the wiring BRL is a wiring that controls the on state and off state of each of the transistor M9 and the transistor M10.

The wiring VDL is a wiring for applying a high-level potential, and the wiring GNDL is a wiring for applying a low-level potential.

Data writing is performed by applying a high-level potential to the wiring WOL and applying a high-level potential to the wiring BRL. Specifically, when the transistor M10 is in an on state, a potential corresponding to information to be stored is applied to the wiring BIL, and the potential is written to a second terminal side of the transistor M10.

In the memory cell 958, an inverter loop is constructed by the transistor MS1 to the transistor MS2; thus, an inverted signal of a data signal corresponding to the potential is input to the second terminal side of the transistor M8. Since the transistor M8 is in an on state, an inverted signal of the potential applied to the wiring BIL, that is, the signal input to the wiring BIL is output to the wiring BILB. Since the transistor M9 and the transistor M10 are in an on state, the potential of the second terminal of the transistor M7 and the potential of the second terminal of the transistor M8 are retained in the first terminal of the capacitor CD2 and the first terminal of the capacitor CD1, respectively. Then, a low-level potential is applied to the wiring WOL and a low-level potential is applied to the wiring BRL to turn on the transistor M7 to the transistor M10 so that the potential of the first terminal of the capacitor CD1 and the potential of the first terminal of the capacitor CD2 are retained.

Data reading is performed in such a manner that after a predetermined potential is precharged to the wiring BIL and the wiring BILB in advance, a high-level potential is applied to the wiring WOL and a high-level potential is applied to the wiring BRL so that the potential of the first terminal of the capacitor CD1 is refreshed by the inverter loop in the memory cell 958 and is output to the wiring BILB. Moreover, the potential of the first terminal of the capacitor CD2 is refreshed by the inverter loop in the memory cell 958 and is output to the wiring BIL. Since the potentials of the wiring BIL and the wiring BILB are changed from the precharged potentials to the potential of the first terminal of the capacitor CD2 and the potential of the first terminal of the capacitor CD1, respectively, the potential retained in the memory cell can be read from the potential of the wiring BIL or the wiring BILB.

Note that an OS transistor is preferably employed as each of the transistor M7 to the transistor M10. Accordingly, written data can be retained for a long time by the transistor M7 to the transistor M10; thus, the frequency of refresh of the memory cell can be reduced. Alternatively, refresh operation of the memory cell can be unnecessary.

Note that a Si transistor may be used as each of the transistor MS1 to the transistor MS4.

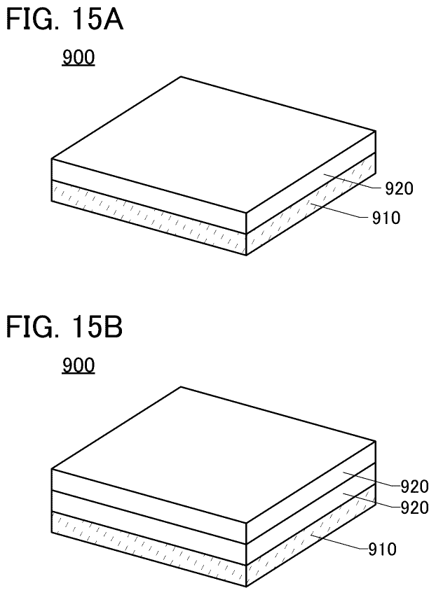

The driver circuit 910 and the memory array 920 that are included in the semiconductor device 900 may be provided on the same plane. As illustrated in FIG. 15A, the driver circuit 910 and the memory array 920 may be provided to overlap with each other. When the driver circuit 910 and the memory array 920 are provided to overlap with each other, the signal transmission distance can be shortened. Alternatively, as illustrated in FIG. 15B, a plurality of memory arrays 920 may be provided over the driver circuit 910.

Next, an example of an arithmetic processing unit that can include the semiconductor device such as the storage device described above.

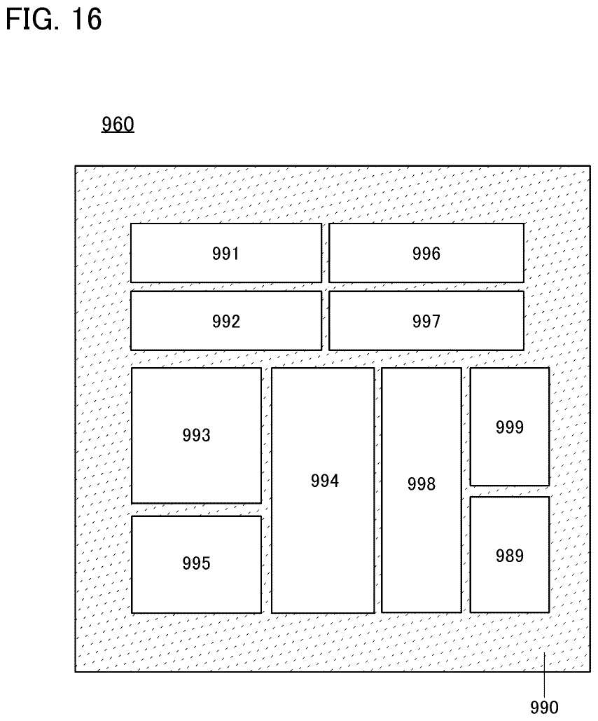

FIG. 16 illustrates a block diagram of an arithmetic unit 960. The arithmetic unit 960 illustrated in FIG. 16 can be employed as a CPU (Central Processing Unit), for example. The arithmetic unit 960 can also be employed as a processor including a larger number of (several tens to several hundreds of) processor cores capable of parallel processing than a CPU, such as a GPU (Graphics Processing Unit), a TPU (Tensor Processing Unit), or an NPU (Neural Processing Unit).

The arithmetic unit 960 illustrated in FIG. 16 includes, over a substrate 990, an ALU 991 (Arithmetic logic unit, arithmetic circuit), an ALU controller 992, an instruction decoder 993, an interrupt controller 994, a timing controller 995, a register 996, a register controller 997, a bus interface 998, a cache 999, and a cache interface 989. A semiconductor substrate, an SOI substrate, a glass substrate, or the like is used as the substrate 990. The arithmetic unit 960 may include a rewritable ROM and a ROM interface. In addition, the cache 999 and the cache interface 989 may be provided in a separate chip.

The cache 999 is connected to a main memory provided in a separate chip through the cache interface 989. The cache interface 989 has a function of supplying part of data retained in the main memory to the cache 999. The cache interface 989 also has a function of outputting part of data retained in the cache 999 to the ALU 991, the register 996, or the like through the bus interface 998.

As described later, the memory array 920 can be stacked and provided over the arithmetic unit 960. The memory array 920 can be used as a cache. In that case, the cache interface 989 may have a function of supplying data retained in the memory array 920 to the cache 999. Moreover, in that case, the driver circuit 910 is preferably included in part of the cache interface 989.

Note that it is also possible that the cache 999 is not provided and only the memory array 920 is used as a cache.

The arithmetic unit 960 illustrated in FIG. 16 is just an example with a simplified structure, and the actual arithmetic unit 960 has a variety of structures depending on the application. For example, what is called a multicore structure is preferably employed in which a plurality of cores each including the arithmetic unit 960 illustrated in FIG. 16 operate in parallel. The larger number of cores can increase arithmetic performance. The number of cores is preferably larger; for example, the number is preferably 2, further preferably 4, still further preferably 8, yet further preferably 12, yet still further preferably 16 or larger. For application requiring extremely high arithmetic performance, e.g., a server, it is preferable to employ the multicore structure including 16 or more, preferably 32 or more, further preferably 64 or more cores. The number of bits that the arithmetic unit 960 can handle with an internal arithmetic circuit, a data bus, or the like can be 8 bits, 16 bits, 32 bits, 64 bits, or the like, for example.

An instruction that is input to the arithmetic unit 960 through the bus interface 998 is input to the instruction decoder 993 and decoded therein, and then, input to the ALU controller 992, the interrupt controller 994, the register controller 997, and the timing controller 995.

The ALU controller 992, the interrupt controller 994, the register controller 997, and the timing controller 995 conduct a variety of control in accordance with the decoded instruction. Specifically, the ALU controller 992 generates signals for controlling the operation of the ALU 991. While the arithmetic unit 960 is executing a program, the interrupt controller 994 judges an interrupt request from an external input/output device, a peripheral circuit, or the like on the basis of its priority, a mask state, or the like and processes the request. The register controller 997 generates the address of the register 996, and reads or writes data from/to the register 996 in accordance with the state of the arithmetic unit 960.

The timing controller 995 generates signals for controlling operation timings of the ALU 991, the ALU controller 992, the instruction decoder 993, the interrupt controller 994, and the register controller 997. For example, the timing controller 995 includes an internal clock generator for generating an internal clock signal on the basis of a reference clock signal, and supplies the internal clock signal to the variety of circuits described above.

In the arithmetic unit 960 illustrated in FIG. 16, the register controller 997 selects retention operation in the register 996 in accordance with an instruction from the ALU 991. That is, the register controller 997 selects whether data is retained by a flip-flop or data is retained by a capacitor in the memory cell included in the register 996. When data retention by the flip-flop is selected, a power supply voltage is supplied to the memory cell in the register 996. When data retention by the capacitor is selected, the data is rewritten to the capacitor, and the supply of a power supply voltage to the memory cell in the register 996 can be stopped.

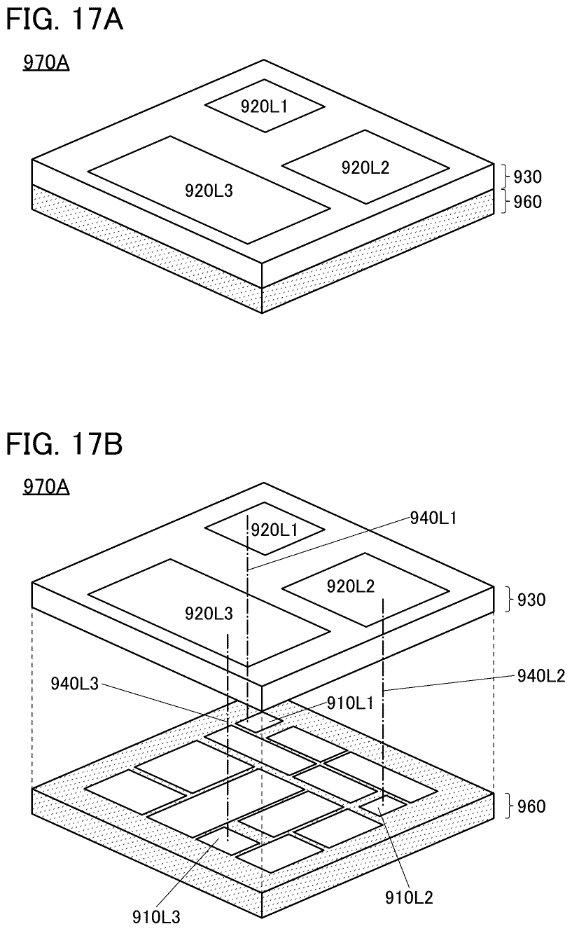

The memory array 920 and the arithmetic unit 960 can be provided to overlap with each other. FIG. 17A and FIG. 17B illustrate perspective views of a semiconductor device 970A. The semiconductor device 970A includes a layer 930 provided with memory arrays over the arithmetic unit 960. A memory array 920L1, a memory array 920L2, and a memory array 920L3 are provided in the layer 930. The arithmetic unit 960 and the memory arrays have regions where they overlap with each other. For easy understanding of the structure of the semiconductor device 970A, the arithmetic unit 960 and the layer 930 are separately illustrated in FIG. 17B.

Providing the arithmetic unit 960 and the layer 930 including the memory arrays to overlap with each other can shorten the connection distance therebetween. Accordingly, communication speed therebetween can be increased. Moreover, since the connection distance is short, power consumption can be reduced.

As a method for stacking the layer 930 including the memory arrays and the arithmetic unit 960, either of the following methods may be employed: a method in which the layer 930 including the memory arrays is stacked directly on the arithmetic unit 960 (also referred to as monolithic stacking), and a method in which the arithmetic unit 960 and the layer 930 are formed over different substrates, the two substrates are attached to each other, and the arithmetic unit 960 and the layer 930 are connected with a through via or by a technique for bonding conductive films (Cu—Cu bonding or the like). The former method does not require consideration of misalignment in attachment; thus, not only chip size but also manufacturing cost can be reduced.

Here, it is possible that the arithmetic unit 960 does not include the cache 999 and the memory arrays 920L1, 920L2, and 920L3 provided in the layer 930 are each used as a cache. In that case, for example, the memory array 920L1, the memory array 920L2, and the memory array 920L3 can be used as an L1 cache (also referred to as a level 1 cache), an L2 cache (also referred to as a level 2 cache), and an L3 cache (also referred to as a level 3 cache), respectively. Among the three memory arrays, the memory array 920L3 has the largest capacity and the lowest access frequency. The memory array 920L1 has the smallest capacity and the highest access frequency.

Note that in the case where the cache 999 provided in the arithmetic unit 960 is used as the L1 cache, the memory arrays provided in the layer 930 can each be used as a lower-level cache or a main memory. The main memory has larger capacity and lower access frequency than the cache.

As illustrated in FIG. 17B, a driver circuit 910L1, a driver circuit 910L2, and a driver circuit 910L3 are provided. The driver circuit 910L1 is connected to the memory array 920L1 through a connection electrode 940L1. Similarly, the driver circuit 910L2 is connected to the memory array 920L2 through a connection electrode 940L2, and the driver circuit 910L3 is connected to the memory array 920L3 through a connection electrode 940L3.

Note that although the case where three memory arrays function as caches is described here, the number of memory arrays may be one, two, or four or more.

In the case where the memory array 920L1 is used as a cache, the driver circuit 910L1 may function as part of the cache interface 989 or the driver circuit 910L1 may be connected to the cache interface 989. Similarly, each of the driver circuit 910L2 and the driver circuit 910L3 may function as part of the cache interface 989 or may be connected thereto.

Whether the memory array 920 functions as the cache or functions as the main memory is determined by the control circuit 912 included in each of the driver circuits 910. The control circuit 912 can make some of the plurality of memory cells 950 included in the semiconductor device 900 each function as a RAM in accordance with a signal supplied from the arithmetic unit 960.

In the semiconductor device 900, some of the plurality of memory cells 950 can each function as the cache and the other memory cells can each function as the main memory. That is, the semiconductor device 900 can have both the function of the cache and the function of the main memory. The semiconductor device 900 according to one embodiment of the present invention can function as a universal memory, for example.

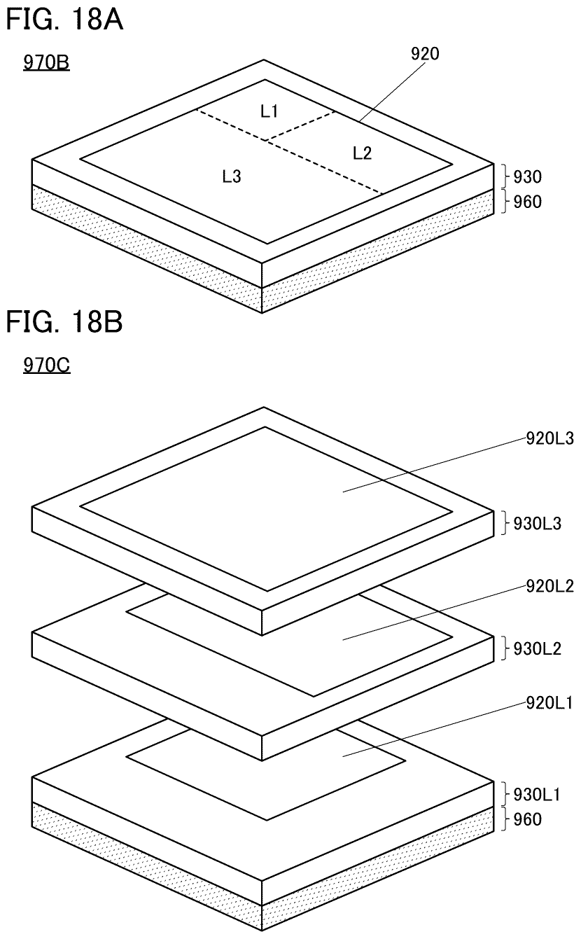

The layer 930 including one memory array 920 may be provided to overlap with the arithmetic unit 960. FIG. 18A illustrates a perspective view of a semiconductor device 970B.

In the semiconductor device 970B, one memory array 920 can be divided into a plurality of areas having different functions. FIG. 18A illustrates an example where a region L1, a region L2, and a region L3 are used as the L1 cache, the L2 cache, and the L3 cache, respectively.

In the semiconductor device 970B, the capacity of each of the region L1 to the region L3 can be changed depending on circumstances. For example, when the capacity of the L1 cache is to be increased, the capacity can be increased by increasing the area of the region L1. With such a structure, arithmetic processing efficiency can be increased and processing speed can be improved.

Alternatively, a plurality of memory arrays may be stacked. FIG. 18B illustrates a perspective view of a semiconductor device 970C.

In the semiconductor device 970C, a layer 930L1 including the memory array 920L1, a layer 930L2 including the memory array 920L2 over the layer 930L1, and a layer 930L3 including the memory array 920L3 over the layer 930L2 are stacked. The memory array 920L1 physically closest to the arithmetic unit 960 can be used as a high-level cache, and the memory array 920L3 physically farthest from the arithmetic unit 960 can be used as a low-level cache or a main memory. Such a structure can increase the capacity of each memory array, which leads to higher processing capability.

Note that this embodiment can be combined with any of the other embodiments in this specification as appropriate.

### Embodiment 5

In this embodiment, application examples of the storage device according to one embodiment of the present invention will be described.

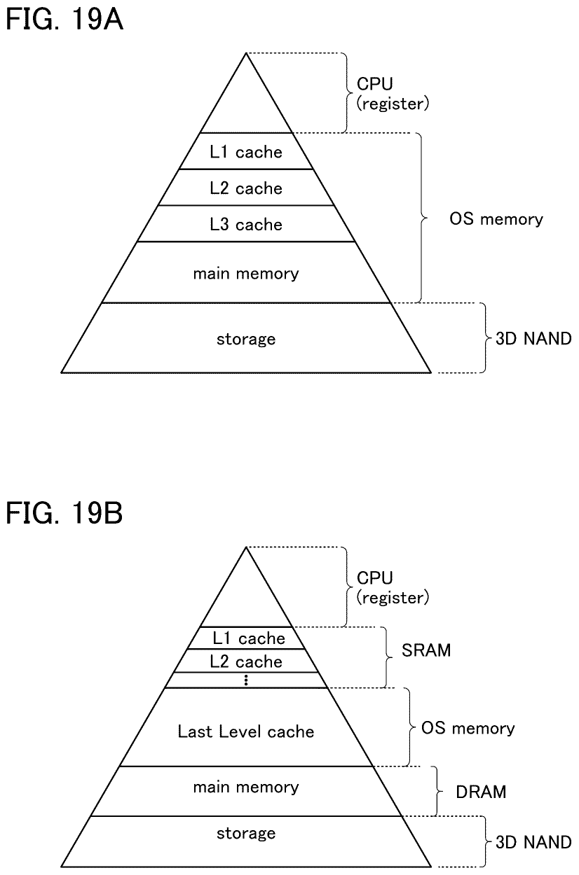

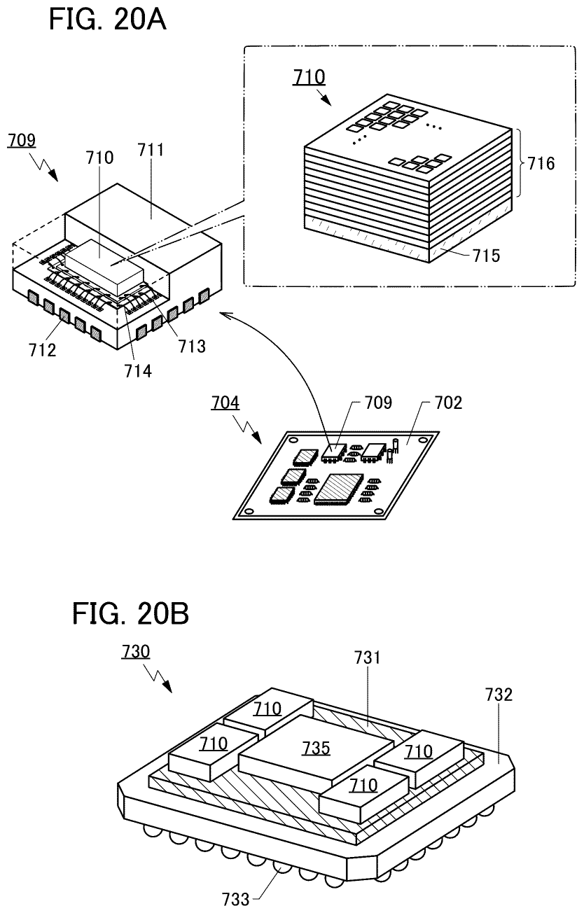

In general, a variety of storage devices are used in semiconductor devices such as computers depending on the intended use. FIG. 19A illustrates the hierarchy of a variety of storage devices used in a semiconductor device. The storage devices at the upper levels require higher operating speed, and the storage devices at the lower levels require larger memory capacity and higher memory density. In FIG. 19A, a memory integrated as a register in an arithmetic processing unit such as a CPU, an L1 cache, an L2 cache, an L3 cache, a main memory, a storage, and the like are provided in this order from the uppermost layer. Note that although the example where the caches up to the L3 cache are included is illustrated here, a lower-level cache may further be included.

A memory integrated as a register in an arithmetic processing unit such as a CPU is used for temporary storage of arithmetic operation results, for example, and thus is frequently accessed by the arithmetic processing unit. Accordingly, high operating speed is required rather than memory capacity. In addition, the register also has a function of retaining setting information of the arithmetic processing unit, for example.

The cache has a function of retaining the copy of part of data retained in a main memory. By duplicating data that is frequently used and retaining the copy of the data in the cache, the access speed to the data can be increased. The cache needs smaller memory capacity than the main memory but higher operating speed than the main memory. In addition, data that is rewritten in the cache is duplicated, and the duplicated data is supplied to the main memory.

The main memory has a function of retaining a program, data, and the like that are read from the storage.

The storage has a function of retaining data that needs to be retained for a long time or a variety of programs used in an arithmetic processing unit, for example. Therefore, the storage needs large memory capacity and high memory density rather than operating speed. For example, a high-capacity nonvolatile storage device such as a 3D NAND can be used.

The storage device using an oxide semiconductor (an OS memory) according to one embodiment of the present invention operates at high speed and can retain data for a long period. Thus, as illustrated in FIG. 19A, the storage device according to one embodiment of the present invention can be suitably used at both the level where the cache is positioned and the level where the main memory is positioned. The storage device of one embodiment of the present invention can also be used at the level where the storage is positioned.

FIG. 19B illustrates an example where an SRAM is employed as some of the caches and the OS memory according to one embodiment of the present invention is employed as the other cache.

The lowest-level cache can be referred to as a last level cache (LLC). The LLC does not require higher operating speed than a higher-level cache, but desirably has large memory capacity. The OS memory according to one embodiment of the present invention operates at high speed and can retain data for a long period, and thus can be suitably used as the LLC. Note that the OS memory according to one embodiment of the present invention can also be used as a final level cache (FLC).

For example, as illustrated in FIG. 19B, an SRAM can be used as each of the higher-level caches (the L1 cache, the L2 cache, and the like), and the OS memory according to one embodiment of the present invention can be used as the LLC. Moreover, a DRAM as well as the OS memory can be employed as the main memory, as illustrated in FIG. 19B.

Note that this embodiment can be combined with any of the other embodiments in this specification as appropriate.

### Embodiment 6

In this embodiment, a transistor including an oxide semiconductor in a channel formation regions (an OS transistor) is described. Note that comparison of an OS transistor with a transistor including silicon in a channel formation region (also referred to as a Si transistor) is briefly described.

### OS Transistor

An oxide semiconductor having a low carrier concentration is preferably used for an OS transistor. For example, the carrier concentration in an oxide semiconductor in a channel formation region is lower than or equal to 1×10¹⁸ cm⁻³, preferably lower than 1×10¹⁷ cm⁻³, further preferably lower than 1×10¹⁶ cm⁻³, still further preferably lower than 1×10¹³ cm⁻³, yet further preferably lower than 1×10¹⁰ cm⁻³, and higher than or equal to 1×10⁻⁹ cm⁻³. Note that in the case where the carrier concentration of an oxide semiconductor film is lowered, the impurity concentration in the oxide semiconductor film is lowered to decrease the density of defect states. In this specification and the like, a state with a low impurity concentration and a low density of defect states is referred to as a highly purified intrinsic or substantially highly purified intrinsic state. Note that an oxide semiconductor having a low carrier concentration is sometimes referred to as a highly purified intrinsic or substantially highly purified intrinsic oxide semiconductor.

In addition, a highly purified intrinsic or substantially highly purified intrinsic oxide semiconductor has a low density of defect states and accordingly has a low density of trap states in some cases. Furthermore, charge captured by the trap states in the oxide semiconductor takes a long time to disappear and might behave like fixed charge. Thus, a transistor whose channel formation region is formed in an oxide semiconductor having a high density of trap states has unstable electrical characteristics in some cases.

Accordingly, in order to stabilize electrical characteristics of the transistor, reducing the impurity concentration in the oxide semiconductor is effective. In addition, in order to reduce the impurity concentration in the oxide semiconductor, it is preferable that the impurity concentration in an adjacent film be also reduced. Examples of impurities include hydrogen and nitrogen. Note that impurities in an oxide semiconductor refer to, for example, elements other than main components of the oxide semiconductor. For example, an element having a concentration lower than 0.1 atomic % can be regarded as an impurity.

In addition, the OS transistor is likely to change its electrical characteristics when impurities and oxygen vacancies exist in the channel formation region in the oxide semiconductor, which might worsen reliability. In some cases, the OS transistor has a defect that is an oxygen vacancy in the oxide semiconductor into which hydrogen enters (hereinafter sometimes referred to as VoH), which generates an electron serving as a carrier. Furthermore, formation of VoH in the channel formation region might increase the donor concentration in the channel formation region. An increase in the donor concentration in the channel formation region might lead to a variation in threshold voltage. Therefore, when the channel formation region in the oxide semiconductor includes oxygen vacancies, the transistor is likely to have normally-on characteristics (characteristics with which, even when no voltage is applied to a gate electrode, a channel exists and current flows through the transistor). Therefore, impurities, oxygen vacancies, and VoH are preferably reduced as much as possible in the channel formation region in the oxide semiconductor.

Furthermore, the bandgap of the oxide semiconductor is preferably wider than the bandgap of silicon (typically 1.1 eV), further preferably wider than or equal to 2 eV, still further preferably wider than or equal to 2.5 eV, yet still further preferably wider than or equal to 3.0 eV. With the use of an oxide semiconductor having a wider bandgap than silicon, the off-state current (also referred to as Ioff) of the transistor can be reduced.

Moreover, in a Si transistor, a short-channel effect (also referred to as an SCE) appears as miniaturization of the transistor proceeds. Thus, it is difficult to miniaturize the Si transistor. One factor in causing the short-channel effect is a narrow bandgap of silicon. In contrast, the OS transistor uses an oxide semiconductor that is a semiconductor material having a wide bandgap, and thus can suppress the short-channel effect. In other words, the OS transistor is a transistor where the short-channel effect does not appear or hardly appears.

Note that the short-channel effect refers to degradation of electrical characteristics that becomes obvious along with miniaturization of a transistor (a decrease in channel length). Specific examples of the short-channel effect include a decrease in threshold voltage, an increase in a subthreshold swing value (sometimes referred to as an S value), and an increase in leakage current. Here, the S value refers to the amount of change in gate voltage which makes drain current change by one digit in a subthreshold region at constant drain voltage.

In addition, characteristic length is widely used as an indicator of resistance to a short-channel effect. The characteristic length is an indicator of the curvature of a potential in a channel formation region. The smaller the characteristic length is, the more steeply the potential rises, which means that smaller characteristic length has higher resistance to the short-channel effect.

The OS transistor is an accumulation-type transistor, and the Si transistor is an inversion-type transistor. Thus, the OS transistor has shorter characteristic length between a source region and the channel formation region and shorter characteristic length between a drain region and the channel formation region than the Si transistor. Accordingly, the OS transistor has higher resistance to the short-channel effect than the Si transistor. That is, the OS transistor is more suitable than the Si transistor in the case where a short-channel transistor is to be manufactured.

Even in the case where the carrier concentration in the oxide semiconductor is reduced until the channel formation region becomes an i-type or substantially i-type region, the conduction band minimum of the channel formation region in a short-channel transistor decreases because of the Conduction-Band-Lowering (CBL) effect; thus, a difference in energy of the conduction band minimum between the channel formation region and the source region or the drain region might decrease to higher than or equal to 0.1 eV and lower than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n⁻-type region and the source region and the drain region become n⁺-type regions.

The OS transistor with the above structure can have favorable electrical characteristics even when a semiconductor device is miniaturized or highly integrated. For example, the OS transistor can have favorable electrical characteristics even when the gate length of the OS transistor is less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. In contrast, it is sometimes difficult for the Si transistor to have a gate length less than or equal to 20 nm or less than or equal to 15 nm due to appearance of the short-channel effect. Thus, the OS transistor can be more suitably used as a short-channel transistor than the Si transistor. Note that the gate length refers to the length of a gate electrode in a direction in which carriers move inside a channel formation region during operation of a transistor, which corresponds to the width of the bottom surface of the gate electrode in a plan view of the transistor.

In addition, miniaturization of the OS transistor can improve the high-frequency characteristics of the transistor. Specifically, the cutoff frequency of the transistor can be improved. When the gate length of the OS transistor is within any of the above ranges, the cutoff frequency of the transistor can be made higher than or equal to 50 GHz, preferably higher than or equal to 100 GHz, further preferably higher than or equal to 150 GHz in a room temperature environment, for example.

As described above, the OS transistor has advantageous effects such as low off-state current and capability of being manufactured with short channel length compared with the Si transistor.

The composition, structure, method, and the like described in this embodiment can be used in combination as appropriate with the compositions, structures, methods, and the like described in the other embodiments and the like.

### Embodiment 7

This embodiment describes an electronic component, an electronic device, a large computer, space equipment, and a data center (also referred to as a DC) that can use the semiconductor device described in the above embodiment. An electronic component, an electronic device, a large computer, space equipment, and a data center each using the semiconductor device according to one embodiment of the present invention are effective in achieving high performance, e.g., reducing power consumption.

### Electronic Component

FIG. 20A illustrates a perspective view of a substrate (a mount board 704) on which an electronic component 709 is mounted. The electronic component 709 illustrated in FIG. 20A includes a semiconductor device 710 in a mold 711. FIG. 20A omits illustrations of some parts to illustrate the inside of the electronic component 709. The electronic component 709 includes lands 712 outside the mold 711. The land 712 is connected to an electrode pad 713, and the electrode pad 713 is connected to the semiconductor device 710 via a wire 714. The electronic component 709 is mounted on a printed circuit board 702, for example. A plurality of such electronic components are combined and connected on the printed circuit board 702, so that the mount board 704 is completed.

In addition, the semiconductor device 710 includes a driver circuit layer 715 and an element layer 716. Note that the element layer 716 has a structure where a plurality of memory cell arrays are stacked. A stacked-layer structure of the driver circuit layer 715 and the element layer 716 can be a monolithic stacked-layer structure. In the monolithic stacked-layer structure, layers can be connected without using a through electrode technique such as a TSV (Through Silicon Via) and a bonding technique such as Cu-Cu direct bonding. The monolithic stacked-layer structure of the driver circuit layer 715 and the element layer 716 enables, for example, what is called an on-chip memory structure where a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as a TSV is employed; thus, the number of connection pins can be increased. The increase in the number of connection pins enables parallel operation, which can improve the bandwidth of the memory (also referred to as memory bandwidth).

Furthermore, it is preferable that the plurality of memory cell arrays included in the element layer 716 be formed using OS transistors and be monolithically stacked. The monolithic stacked-layer structure of a plurality of memory cell arrays can improve one or both of the bandwidth of the memory and the access latency of the memory. Note that the bandwidth refers to the data transfer amount per unit time, and the access latency refers to time between data access and start of data transmission. Note that in the case where Si transistors are used for the element layer 716, the monolithic stacked-layer structure is difficult to form as compared with the case where OS transistors are used for the element layer 716. Therefore, the OS transistors are superior to the Si transistors in the monolithic stacked-layer structure.

Moreover, the semiconductor device 710 may be called a die. Note that in this specification and the like, a die refers to a chip piece obtained by, for example, forming a circuit pattern on a disc-like substrate (also referred to as a wafer) or the like and cutting the substrate into dies in a process of manufacturing a semiconductor chip. Note that examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

Next, FIG. 20B illustrates a perspective view of an electronic component 730. The electronic component 730 is an example of a SiP (System in Package) or an MCM (Multi Chip Module). In the electronic component 730, an interposer 731 is provided on a package substrate 732 (a printed circuit board), and a semiconductor device 735 and a plurality of semiconductor devices 710 are provided on the interposer 731.

The electronic component 730 using the semiconductor devices 710 as high bandwidth memories (HBM) is illustrated as an example. In addition, the semiconductor device 735 can be used for an integrated circuit such as a CPU (Central Processing Unit), a GPU (Graphics Processing Unit), or an FPGA (Field Programmable Gate Array).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of connecting a plurality of integrated circuits with different terminal pitches. The plurality of wirings are provided in a single layer or multiple layers. The interposer 731 also has a function of connecting an integrated circuit provided on the interposer 731 to an electrode provided on the package substrate 732. Accordingly, the interposer is sometimes referred to as a “redistribution substrate” or an “intermediate substrate”. Furthermore, a through electrode is provided in the interposer 731 and the through electrode is used to connect an integrated circuit and the package substrate 732 in some cases. Moreover, in a silicon interposer, a TSV can also be used as the through electrode.

In an HBM, many wirings need to be connected to achieve wide memory bandwidth. Therefore, an interposer on which an HBM is mounted requires minute and densely formed wirings. For this reason, a silicon interposer is preferably used as the interposer on which an HBM is mounted.

In addition, in a SiP, an MCM, and the like each using a silicon interposer, a decrease in reliability due to a difference in an expansion coefficient between an integrated circuit and the interposer does not easily occur. Furthermore, a surface of a silicon interposer has high planarity, and poor connection between the silicon interposer and an integrated circuit provided on the silicon interposer does not easily occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are connected using a silicon interposer, a TSV, and the like, a space for the width of the terminal pitch and the like is needed. Accordingly, in the case where the size of the electronic component 730 is to be reduced, the width of the terminal pitch becomes an issue, which sometimes makes it difficult to provide a large number of wirings for achieving a wide memory bandwidth. For this reason, the monolithic stacked-layer structure using the OS transistors is suitable, as described above. A composite structure where memory cell arrays stacked using a TSV and monolithically stacked memory cell arrays are combined may be employed.

In addition, a heat sink (a radiator plate) may be provided to overlap with the electronic component 730. In the case where a heat sink is provided, the heights of integrated circuits provided on the interposer 731 are preferably aligned with each other. For example, in the electronic component 730 described in this embodiment, the heights of the semiconductor devices 710 and the semiconductor device 735 are preferably aligned with each other.

Electrodes 733 may be provided on a bottom portion of the package substrate 732 to mount the electronic component 730 on another substrate. FIG. 20B illustrates an example where the electrodes 733 are formed of solder balls. When the solder balls are provided in a matrix on the bottom portion of the package substrate 732, BGA (Ball Grid Array) mounting can be achieved. Alternatively, the electrodes 733 may be formed of conductive pins. When the conductive pins are provided in a matrix on the bottom portion of the package substrate 732, PGA (Pin Grid Array) mounting can be achieved.

The electronic component 730 can be mounted on another substrate by a variety of mounting methods not limited to BGA and PGA. Examples of mounting methods include SPGA (Staggered Pin Grid Array), LGA (Land Grid Array), QFP (Quad Flat Package), QFJ (Quad Flat J-leaded package), and QFN (Quad Flat Non-leaded package).

### Electronic Device

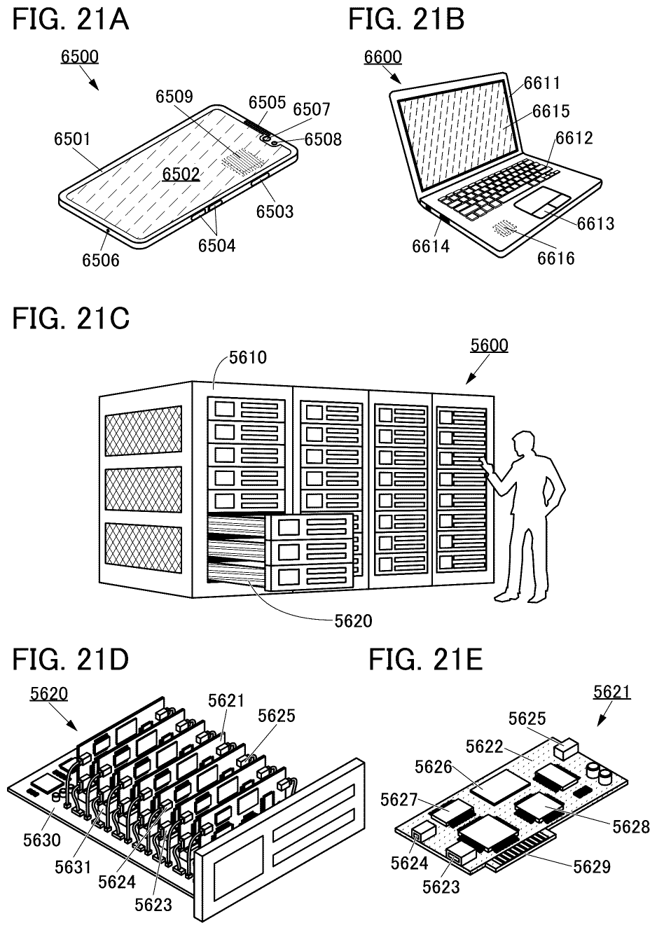

Next, FIG. 21A illustrates a perspective view of an electronic device 6500. The electronic device 6500 illustrated in FIG. 21A is a portable information terminal that can be used for a smartphone. The electronic device 6500 includes a housing 6501, a display portion 6502, a power button 6503, buttons 6504, a speaker 6505, a microphone 6506, a camera 6507, a light source 6508, a control device 6509, and the like. Note that the control device 6509 includes one or more selected from a CPU, a GPU, and a storage device, for example. The semiconductor device according to one embodiment of the present invention can be employed for the display portion 6502, the control device 6509, or the like.

An electronic device 6600 illustrated in FIG. 21B is an information terminal that can be used for a laptop personal computer. The electronic device 6600 includes a housing 6611, a keyboard 6612, a pointing device 6613, an external connection port 6614, a display portion 6615, a control device 6616, and the like. Note that the control device 6616 includes one or more selected from a CPU, a GPU, and a storage device, for example. The semiconductor device according to one embodiment of the present invention can be employed for the display portion 6615, the control device 6616, or the like. Note that the semiconductor device according to one embodiment of the present invention is suitably used for each of the control device 6509 and the control device 6616 because power consumption can be reduced.

### Large Computer

Next, FIG. 21C illustrates a perspective view of a large computer 5600. In the large computer 5600 illustrated in FIG. 21C, a plurality of rack mount computers 5620 are stored in a rack 5610. Note that the large computer 5600 may also be referred to as a supercomputer.

The computer 5620 can have a structure in a perspective view illustrated in FIG. 21D, for example. In FIG. 21D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 21E is an example of a processing board provided with a CPU, a GPU, a storage device, and the like. The PC card 5621 includes a board 5622. In addition, the board 5622 includes the connection terminal 5623, the connection terminal 5624, the connection terminal 5625, a semiconductor device 5626, a semiconductor device 5627, a semiconductor device 5628, and a connection terminal 5629. Note that FIG. 21E also illustrates semiconductor devices other than the semiconductor device 5626, the semiconductor device 5627, and the semiconductor device 5628; the following description of the semiconductor device 5626, the semiconductor device 5627, and the semiconductor device 5628 is referred to for these semiconductor devices.

The connection terminal 5629 has a shape that can be inserted in the slot 5631 of the motherboard 5630, and the connection terminal 5629 functions as an interface for connecting the PC card 5621 and the motherboard 5630. An example of the standard for the connection terminal 5629 is PCIe or the like.

The connection terminal 5623, the connection terminal 5624, and the connection terminal 5625 can each serve as, for example, an interface for performing power supply, signal input, or the like to the PC card 5621. As another example, the connection terminal 5623, the connection terminal 5624, and the connection terminal 5625 can each serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In addition, in the case where video signals are output from the connection terminal 5623, the connection terminal 5624, and the connection terminal 5625, an example of the standard for each of the connection terminal 5623, the connection terminal 5624, and the connection terminal 5625 is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be connected.

The semiconductor device 5627 includes a plurality of terminals, and when the terminals are reflow-soldered, for example, to wirings of the board 5622, the semiconductor device 5627 and the board 5622 can be connected. Examples of the semiconductor device 5627 include an FPGA, a GPU, and a CPU. The electronic component 730 can be used for the semiconductor device 5627, for example.

The semiconductor device 5628 includes a plurality of terminals, and when the terminals are reflow-soldered, for example, to wirings of the board 5622, the semiconductor device 5628 and the board 5622 can be connected. An example of the semiconductor device 5628 is a storage device. The electronic component 709 can be used for the semiconductor device 5628, for example.

The large computer 5600 can also function as a parallel computer. When the large computer 5600 is used as a parallel computer, large-scale computation necessary for artificial intelligence learning and inference can be performed, for example.

### Space Equipment

The semiconductor device according to one embodiment of the present invention can be suitably used for space equipment such as equipment that processes and stores information.

The semiconductor device according to one embodiment of the present invention can include an OS transistor. A change in electrical characteristics of the OS transistor due to exposure to radiation is small. That is, the OS transistor is highly resistant to radiation and thus can be suitably used in an environment where radiation can enter. For example, the OS transistor can be suitably used in the case of being used in outer space.

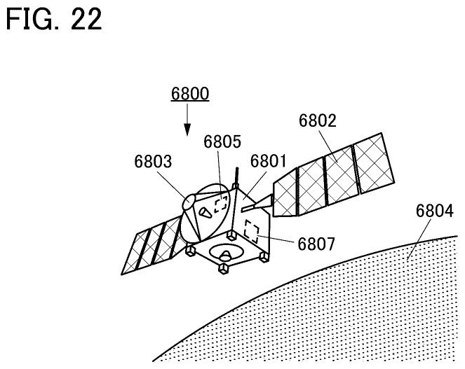

FIG. 22 illustrates an artificial satellite 6800 as an example of space equipment. The artificial satellite 6800 includes a body 6801, solar panels 6802, an antenna 6803, a secondary battery 6805, and a control device 6807. Note that FIG. 22 illustrates a planet 6804 in outer space, for example. Note that outer space refers to, for example, space at an altitude greater than or equal to 100 km, and outer space described in this specification may include the thermosphere, the mesosphere, and the stratosphere.

In addition, although not illustrated in FIG. 22, a battery management system (also referred to as a BMS) or a battery control circuit may be provided in the secondary battery 6805. An OS transistor is suitably used in the battery management system or the battery control circuit because low power consumption and high reliability even in outer space are achieved.

Furthermore, the amount of radiation in outer space is 100 or more times that on the ground. Note that examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for the operation of the artificial satellite 6800 is generated. However, for example, in a situation where the solar panel is not irradiated with sunlight or in a situation where the amount of sunlight with which the solar panel is irradiated is small, the amount of generated electric power is small. Accordingly, electric power required for the operation of the artificial satellite 6800 might not be generated. In order to operate the artificial satellite 6800 even in the situation where the amount of generated electric power is small, the artificial satellite 6800 is preferably provided with the secondary battery 6805. Note that the solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

In addition, the control device 6807 has a function of controlling the artificial satellite 6800. The control device 6807 is formed using one or more selected from a CPU, a GPU, and a storage device, for example. Note that the semiconductor device according to one embodiment of the present invention is suitably used for the control device 6807. A change in electrical characteristics due to exposure to radiation is smaller in an OS transistor than in a Si transistor. That is, the OS transistor has high reliability and thus can be suitably used even in an environment where radiation can enter.

Alternatively, the artificial satellite 6800 can include a sensor. For example, when the artificial satellite 6800 includes a visible light sensor, the artificial satellite 6800 can have a function of detecting sunlight reflected by a ground-based object. Alternatively, when the artificial satellite 6800 includes a thermal infrared sensor, the artificial satellite 6800 can have a function of detecting thermal infrared rays emitted from the surface of the earth. Thus, the artificial satellite 6800 can have a function of an earth observing satellite, for example.

Note that although the artificial satellite is illustrated as an example of space equipment in this embodiment, the present invention is not limited thereto. The semiconductor device according to one embodiment of the present invention can be suitably used for space equipment such as a spacecraft, a space capsule, or a space probe, for example.

As described above, the OS transistor has excellent effects of achieving a wide memory bandwidth and being highly resistant to radiation as compared with the Si transistor.

### Data Center

The semiconductor device according to one embodiment of the present invention can be suitably used for, for example, a storage system employed in a data center or the like. Long-term data management, such as a guarantee for data immutability, is required for the data center. The long-term data management needs increasing the scale of the data center, such as installing a storage and a server for storing an enormous amount of data, ensuring a stable power source for data retention, and ensuring cooling equipment required for data retention.

With the use of the semiconductor device according to one embodiment of the present invention for a storage system employed in a data center, electric power required for data retention can be reduced and a semiconductor device that retains data can be downsized. Accordingly, downsizing of the storage system, downsizing of a power source for data retention, downscaling of cooling equipment, and the like can be achieved. Therefore, space saving of the data center can be achieved.

In addition, since the semiconductor device according to one embodiment of the present invention has low power consumption, heat generation from a circuit can be reduced. Accordingly, it is possible to reduce adverse effects of the heat generation on the circuit itself, a peripheral circuit, and a module. Furthermore, the use of the semiconductor device according to one embodiment of the present invention can achieve a data center that stably operates even in a high-temperature environment. Thus, the reliability of the data center can be increased.

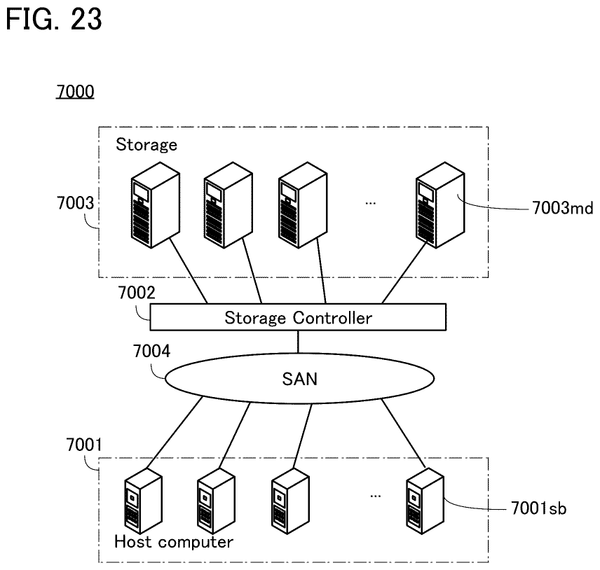

FIG. 23 illustrates a storage system applicable to a data center. A storage system 7000 illustrated in FIG. 23 includes a plurality of servers 7001sb as a host 7001 (indicated as “Host Computer” in the diagram). In addition, the storage system 7000 includes a plurality of storage devices 7003md as a storage 7003 (indicated as “Storage” in the diagram). In the illustrated example, the host 7001 and the storage 7003 are connected through a storage area network 7004 (indicated as “SAN” in the diagram) and a storage control circuit 7002 (indicated as “Storage Controller” in the diagram).

The host 7001 corresponds to a computer that accesses data stored in the storage 7003. The hosts 7001 may be connected to each other through a network.

The data access speed, i.e., the time taken for storing and outputting data, of the storage 7003 is shortened by using a flash memory, but is considerably longer than the data access speed of a DRAM that can be used as a cache memory in a storage. In the storage system, in order to solve the problem of low access speed of the storage 7003, a cache memory is usually provided in a storage to shorten the time taken for storing and outputting data.

The cache memories are used in the storage control circuit 7002 and the storage 7003. Data transmitted between the host 7001 and the storage 7003 are stored in the cache memories in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downsizing is possible by stacking memory cell arrays.

Note that the use of the semiconductor device according to one embodiment of the present invention for one or more selected from an electronic component, an electronic device, a large computer, space equipment, and a data center is expected to produce an effect of reducing power consumption. While the demand for energy is expected to increase with higher performance or higher integration of semiconductor devices, the emission amount of greenhouse effect gases typified by carbon dioxide (CO₂) can be reduced with the use of the semiconductor device according to one embodiment of the present invention. Furthermore, the semiconductor device according to one embodiment of the present invention has low power consumption and thus is effective as a global warming countermeasure.

The composition, structure, method, and the like described in this embodiment can be used in combination as appropriate with the compositions, structures, methods, and the like described in the other embodiments and the like.

### Supplementary Notes on the Description in this Specification and the Like

The description of the above embodiments and each structure in the embodiments are noted below.

One embodiment of the present invention can be constituted by combining, as appropriate, the structure described in each embodiment with the structures described in the other embodiments. In addition, in the case where a plurality of structure examples are described in one embodiment, the structure examples can be combined as appropriate.

Note that content (or may be part of the content) described in one embodiment can be applied to, combined with, or replaced with another content (or may be part of the content) described in the embodiment and/or content (or may be part of the content) described in another embodiment or other embodiments.

Note that in each embodiment, content described in the embodiment is content described using a variety of diagrams or content described with text disclosed in the specification.

Note that by combining a diagram (or may be part thereof) described in one embodiment with another part of the diagram, a different diagram (or may be part thereof) described in the embodiment, and/or a diagram (or may be part thereof) described in another embodiment or other embodiments, much more diagrams can be formed.

In addition, in this specification and the like, components are classified on the basis of the functions, and shown as blocks independent of one another in block diagrams. However, in an actual circuit or the like, it is difficult to separate components on the basis of the functions, and there is such a case where one circuit is associated with a plurality of functions or a case where a plurality of circuits are associated with one function. Therefore, blocks in the block diagrams are not limited by the components described in this specification, and the description can be changed appropriately depending on the situation.

Furthermore, in the drawings, the size, the layer thickness, or the region is shown with given magnitude for description convenience. Therefore, the size, the layer thickness, or the region is not necessarily limited to the illustrated scale. Note that the drawings are schematically shown for clarity, and embodiments of the present invention are not limited to shapes, values or the like shown in the drawings. For example, variation in signal, voltage, or current due to noise, variation in signal, voltage, or current due to difference in timing, or the like can be included.

In this specification and the like, expressions “one of a source and a drain” (or a first electrode or a first terminal) and “the other of the source and the drain” (or a second electrode or a second terminal) are used in the description of the connection relationship of a transistor. This is because the source and the drain of the transistor change depending on the structure, operating conditions, or the like of the transistor. Note that the source or the drain of the transistor can also be referred to as a source (drain) terminal, a source (drain) electrode, or the like as appropriate depending on the situation.

In addition, in this specification and the like, the term “electrode” or “wiring” does not limit the function of the component. For example, an “electrode” is used as part of a “wiring” in some cases, and vice versa. Furthermore, the term “electrode” or “wiring” also includes the case where a plurality of “electrodes” or “wirings” are formed in an integrated manner, for example.

Furthermore, in this specification and the like, “voltage” and “potential” can be interchanged with each other as appropriate. The voltage refers to a potential difference from a reference potential, and when the reference potential is a ground voltage, for example, the voltage can be rephrased into the potential. The ground potential does not necessarily mean 0 V. Note that potentials are relative values, and a potential applied to a wiring or the like is sometimes changed depending on the reference potential.

Note that in this specification and the like, the terms such as “film” and “layer” can be interchanged with each other depending on the case or according to circumstances. For example, the term “conductive layer” can be changed into the term “conductive film” in some cases. As another example, the term “insulating film” can be changed into the term “insulating layer” in some cases.

In this specification and the like, a switch has a function of controlling whether current flows or not by being in a conduction state (an ON state) or a non-conduction state (an OFF state). Alternatively, a switch has a function of selecting and changing a current path.

In this specification and the like, channel length refers to, for example, the distance between a source and a drain in a region where a semiconductor (or a portion where current flows in a semiconductor when a transistor is in an ON state) and a gate overlap with each other or a region where a channel is formed in a top view of the transistor.

In this specification and the like, channel width refers to, for example, the length of a portion where a source and a drain face each other in a region where a semiconductor (or a portion where current flows in a semiconductor when a transistor is in an ON state) and a gate electrode overlap with each other or a region where a channel is formed.

In this specification and the like, a node can be referred to as a terminal, a wiring, an electrode, a conductive layer, a conductor, an impurity region, or the like depending on a circuit structure, a device structure, or the like. Furthermore, a terminal, a wiring, or the like can be referred to as a node.

In this specification and the like, the expression “A and B are connected” means the case where A and B are electrically connected. Here, the expression “A and B are electrically connected” means connection that enables electrical signal transmission between A and B in the case where an object (that refers to an element such as a switch, a transistor element, or a diode, a circuit including the element and a wiring, or the like) exists between A and B. Note that the case where A and B are electrically connected includes the case where A and B are directly connected. Here, the expression “A and B are directly connected” means connection that enables electrical signal transmission between A and B through a wiring (or an electrode) or the like, not through the above object. In other words, direct connection refers to connection that can be regarded as the same circuit diagram when indicated as an equivalent circuit.

### Reference Numerals

10: semiconductor device, 20: element layer, 21: word line driver circuit, 22: bit line driver circuit, 23: memory controller portion, 25: element layer, 30_1: element layer, 30_2: element layer, 30_3: element layer, 30_4: element layer, 30_n: element layer, 30: element layer, 31_1: memory circuit, 31_2: memory circuit, 31_3: memory circuit, 31_4: memory circuit, 31: memory circuit, 32_1: memory cell, 32_2: memory cell, 32_3: memory cell, 32_4: memory cell, 32_n: memory cell, 32: memory cell, 37: transistor, 38_1: transistor, 38_2: transistor, 38_3: transistor, 38_4: transistor, 39_1: transistor, 39_2: transistor, 39_3: transistor, 39_4: transistor, 40: capacitor

1. A semiconductor device comprising:
a first element layer; and
a second element layer comprising n element layers,
wherein n is an integer greater than or equal to 2,
wherein the second element layer is provided over the first element layer,
wherein a bit line driver circuit is provided in the first element layer,
wherein a memory circuit is provided in the second element layer,
wherein the memory circuit comprises n memory cells each of which is configured to retain n-bit data,
wherein the memory cell comprises a first transistor and a second transistor and is configured to retain a potential corresponding to the data by turning off the first transistor and configured to allow a current with an amount corresponding to the data to flow by applying the potential to a gate of the second transistor,
wherein the bit line driver circuit is configured to write, to the n memory cells, a potential corresponding to the data through a first wiring and configured to read, from the n memory cells, a current with an amount corresponding to the data through a second wiring, and
wherein a parallel number of the second transistors electrically connected to the second wiring is different between the n memory cells, and the parallel number corresponds to a power of two.

2. The semiconductor device according to claim 1,
wherein the first element layer comprises the first transistor comprising a first semiconductor layer comprising silicon in a channel formation region, and
wherein the second element layer comprises the second transistor comprising a second semiconductor layer comprising an oxide semiconductor in a channel formation region.

3. The semiconductor device according to claim 2,
wherein the oxide semiconductor comprises at least In.

4. The semiconductor device according to claim 1,
wherein each of the first wiring and the second wiring comprises a portion provided in a direction perpendicular to a substrate provided with the first element layer.
